(19) United States
(12) Patent Application Publication
(10) Pub. No.: US 2024/0353753 A1
(43) Pub. Date: Oct. 24, 2024

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR PRODUCING ELECTRONIC DEVICE

(71) Applicant: FUJIFILM Corporation, Tokyo (JP)

(72) Inventors: Asahi TAKAKI, Haibara-gun (JP); Hideaki TSUBAKI, Haibara-gun (JP); Takamitsu TOMIGA, Haibara-gun (JP)

(73) Assignee: FUJIFILM Corporation, Tokyo (JP)

(21) Appl. No.: 18/621,915

(22) Filed: Mar. 29, 2024

(30) Foreign Application Priority Data
Mar. 31, 2023 (JP) 2023-059561

(51) Int. Cl. G03F 7/004

(52) U.S. Cl. CPC G03F 7/0045

(57) ABSTRACT

An actinic ray-sensitive or radiation-sensitive resin composition having a concentration of solid contents of 15% or more, the resin composition containing (A) a resin including a repeating unit (a1) having an acid-decomposable group and a repeating unit (a2) having an aromatic ring, (B) a resin including a repeating unit (b1) represented by a specified general formula (1), and (C) a compound that generates an acid upon irradiation with an actinic ray or a radiation. A content of a repeating unit having an acid-decomposable group and included in the resin (B) is 5 mol % or less relative to all repeating units in the resin (B), and the resin (B) has a dispersity of less than 3.0.

### CROSS-REFERENCE TO RELATED APPLICATIONS

This application is based upon and claims the benefit of priority from prior Japanese patent application No. 2023-059561, filed on Mar. 31, 2023, the entire contents of which are incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for producing an electronic device.

### 2. Description of the Related Art

In processes for manufacturing semiconductor devices such as integrated circuits (ICs) and large-scale integrated circuits (LSIs), microfabrication by lithography using actinic ray-sensitive or radiation-sensitive resin compositions is performed.

An example of the lithography method is a method including forming a resist film using an actinic ray-sensitive or radiation-sensitive resin composition, subsequently exposing the obtained resist film, and subsequently performing development to form a resist pattern.

A known example of such an actinic ray-sensitive or radiation-sensitive resin composition is a composition that contains a resin (acid decomposable resin) including a repeating unit having an acid-decomposable group.

In recent years, an actinic ray-sensitive or radiation-sensitive resin composition suitable for pattern formation using a thick resist film has also been proposed (refer to, for example, JP2021-92659A). JP2021-92659A describes a resist composition including a resin component that includes a repeating unit having an acid-decomposable group and a plasticizer component that does not include an acid-dissociable group.

### SUMMARY OF THE INVENTION

However, with regard to pattern formation using a thick resist film, as a result of studies conducted by the inventors of the present invention, it has been found that there is room for further improvement in the reduction of defects in a pattern formed after a composition for pattern formation is stored over time (hereinafter, these defects are also simply referred to as “defects in a pattern after the lapse of time”).

An object of the present invention is to provide an actinic ray-sensitive or radiation-sensitive resin composition that can reduce defects in a pattern after the lapse of time, and an actinic ray-sensitive or radiation-sensitive film, a pattern forming method, and a method for producing an electronic device that use the actinic ray-sensitive or radiation-sensitive resin composition.

The inventors of the present invention have found that the above object can be achieved by the following configurations.

[1]

An actinic ray-sensitive or radiation-sensitive resin composition having a concentration of solid contents of 15% or more, the resin composition containing:
(A) a resin including a repeating unit (a1) having an acid-decomposable group and a repeating unit (a2) having an aromatic ring;
(B) a resin including a repeating unit (b1) represented by General formula (1) below; and
(C) a compound that generates an acid upon irradiation with an actinic ray or a radiation,
wherein a content of a repeating unit having an acid-decomposable group and included in the resin (B) is 5 mol % or less relative to all repeating units in the resin (B), and the resin (B) has a dispersity of less than 3.0.

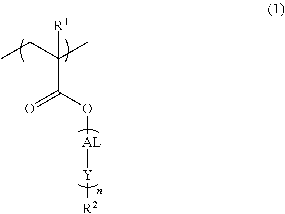

In General formula (1),
R¹ and R² each independently represent a hydrogen atom or a hydrocarbon group.
AL represents a linear or branched alkylene group. When n represents an integer of 2 or more, a plurality of AL's may be the same or different from each other. However, each AL does not include an acid-decomposable group.
Y represents —O—, —S—, —COO—, or —OCO—. When n represents an integer of 2 or more, a plurality of Y's may be the same or different from each other.
n represents an integer of 1 or more.
   [2]

The actinic ray-sensitive or radiation-sensitive resin composition according to [1], wherein, in General formula (1) above, AL is an ethylene group, and Y is —O—.

[3]

The actinic ray-sensitive or radiation-sensitive resin composition according to [1] or [2], wherein the resin (B) includes a repeating unit (b2) having a carboxyl group or a hydroxyl group.

[4]

The actinic ray-sensitive or radiation-sensitive resin composition according to any one of [1] to [3], wherein a content of the resin (B) is 50 parts by mass or less relative to 100 parts by mass of the resin (A).

[5]

The actinic ray-sensitive or radiation-sensitive resin composition according to any one of [1] to [4], wherein the resin (B) does not substantially include a fluorine atom or a silicon atom.

[6]

The actinic ray-sensitive or radiation-sensitive resin composition according to any one of [1] to [5], wherein a content of a compound having an ethylenically unsaturated bond and included in the composition is 1.0 mass % or less in a total solid content.

[7]

The actinic ray-sensitive or radiation-sensitive resin composition according to any one of [1] to [6], wherein, in a chromatogram obtained by gel permeation chromatography (GPC) of the resin (B), an area of a component having a weight-average molecular weight (Mw_{B}) of 10,000 or less is 20% or less with respect to a total area excluding peak areas of an unreacted polymerizable monomer and a polymerization solvent, and the resin (B) has a Mw_{B} of 90,000 or less.

[8]

An actinic ray-sensitive or radiation-sensitive film formed from the actinic ray-sensitive or radiation-sensitive resin composition according to any one of [1] to [7].

[9]

A pattern forming method having a step of forming an actinic ray-sensitive or radiation-sensitive film on a substrate from the actinic ray-sensitive or radiation-sensitive resin composition according to any one of [1] to [7]; a step of exposing the actinic ray-sensitive or radiation-sensitive film; and a step of developing the exposed actinic ray-sensitive or radiation-sensitive film with a developer to form a pattern.

[10]

A method for producing an electronic device, the method including the pattern forming method according to [9].

The present invention can provide an actinic ray-sensitive or radiation-sensitive resin composition that can reduce defects in a pattern after the lapse of time, and an actinic ray-sensitive or radiation-sensitive film, a pattern forming method, and a method for producing an electronic device that use the actinic ray-sensitive or radiation-sensitive resin composition.

### DESCRIPTION OF THE PREFERRED EMBODIMENTS

Hereinafter, examples of embodiments for carrying out the present invention will be described.

In the present specification, a range of numerical values expressed with “to” means a range that includes a numerical value before “to” as a lower limit value and a numerical value after “to” as an upper limit value.

In the expression of groups (atomic groups) in the present specification, an expression without the term of substituted or unsubstituted encompasses, in addition to groups having no substituents, groups having substituents. For example, “alkyl group” encompasses not only an alkyl group having no substituent (unsubstituted alkyl group) but also alkyl groups having substituents (substituted alkyl groups). In the present specification, “organic group” refers to a group including at least one carbon atom.

In the present specification, in the case of using a phrase “may have a substituent”, the type of the substituent, the position of the substituent, and the number of such substituents are not particularly limited. The number of the substituents may be, for example, one, two, three, or more. Examples of the substituent include monovalent non-metallic atomic groups excluding a hydrogen atom and, for example, can be selected from substituent T below.

### Substituent T

Examples of substituent T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; alkyl groups; cycloalkyl groups; aryl groups; heteroaryl groups; a hydroxyl group; a carboxy group; a formyl group; a sulfo group; a cyano group; alkylaminocarbonyl groups; arylaminocarbonyl groups; a sulfonamide group; a silyl group; an amino group; monoalkylamino groups; dialkylamino groups; arylamino groups; a nitro group; and combinations of the foregoing.

The bonding direction of a divalent group expressed in the present specification is not limited unless otherwise specified. For example, in a compound represented by a general formula “L-M-N” where M is —OCO—C(CN)—CH—, when a position bonded to the L side is represented by *1 and a position bonded to the N side is represented by *2, M may be *1-OCO—C(CN)═CH-*2 or *1-CH═C(CN)—COO-*2.

In the present specification, “(meth)acrylic” is a collective term for “acrylic” and “methacrylic” and means “at least one of acrylic or methacrylic”. Similarly, “(meth)acrylic acid” is a collective term for “acrylic acid” and “methacrylic acid” and means “at least one of acrylic acid or methacrylic acid”.

In the present specification, a weight-average molecular weight (Mw), a number-average molecular weight (Mn), a Z− average molecular weight (Mz), and a molecular weight distribution (also referred to as a dispersity) (Mw/Mn) of a resin are defined as polystyrene-equivalent values determined, using a GPC (Gel Permeation Chromatography) apparatus (HLC-8120GPC manufactured by Tosoh Corporation), by GPC measurement (solvent: tetrahydrofuran, amount of flow (amount of sample injected): 10 μL, column: TSK gel Multipore HXL-M manufactured by Tosoh Corporation, column temperature: 40° C., flow rate: 1.0 mL/min, detector: differential refractive index detector (Refractive Index Detector)).

In the present specification, “actinic ray” or “radiation” means, for example, an emission line spectrum of a mercury lamp, far ultraviolet rays represented by an excimer laser, extreme ultraviolet rays (EUV: Extreme Ultraviolet), X-rays, or an electron beam (EB: Electron Beam). In the present specification, “light” means an actinic ray or a radiation.

In the present specification, “exposure” includes, unless otherwise specified, not only exposure with, for example, an emission line spectrum of a mercury lamp, far ultraviolet rays represented by an excimer laser, extreme ultraviolet rays, or X-rays but also patterning with an electron beam or a corpuscular beam such as an ion beam.

### Actinic Ray-Sensitive or Radiation-Sensitive Resin Composition

An actinic ray-sensitive or radiation-sensitive resin composition according to the present invention (hereinafter, also referred to as a “composition according to the present invention”) is an actinic ray-sensitive or radiation-sensitive resin composition having
a concentration of solid contents of 15% or more, and containing
(A) a resin including a repeating unit (a1) having an acid-decomposable group and a repeating unit (a2) having an aromatic ring,
(B) a resin including a repeating unit (b1) represented by General formula (1) below, and
(C) a compound that generates an acid upon irradiation with an actinic ray or a radiation,
wherein a content of a repeating unit having an acid-decomposable group and included in the resin (B) is 5 mol % or less relative to all repeating units in the resin (B), and the resin (B) has a dispersity of less than 3.0.

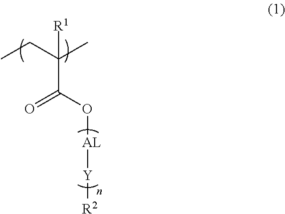

In General formula (1),

R¹ and R² each independently represent a hydrogen atom or a hydrocarbon group.
AL represents a linear or branched alkylene group. When n represents an integer of 2 or more, a plurality of AL's may be the same or different from each other. However, each AL does not include an acid-decomposable group.
Y represents —O—, —S—, —COO—, or —OCO—. When n represents an integer of 2 or more, a plurality of Y's may be the same or different from each other.
n represents an integer of 1 or more.

The reason why the defects in a pattern after the lapse of time can be reduced by the composition according to the present invention is not completely clarified, but the inventors of the present invention presume as follows.

Since a composition for forming a thick film generally has a high concentration of solid contents, aggregation of a component included in the composition is likely to occur during storage of the composition over time, and there is room for improvement with respect to defects in a pattern after the lapse of time.

In view of the above, first, by adjusting the dispersity of the resin (B) included in the composition according to the present invention, which is expected to function as a plasticizer in the film, to less than 3.0, presumably, aggregation of the resin (B) can be further suppressed even when the composition according to the present invention is stored over time, the mass distribution of the resin (B) in the film obtained from the composition after storage over time can be made uniform, and furthermore, the number of defects in the obtained pattern can be reduced.

In addition, the resin (B) has the structure of the repeating unit (b1); therefore, it is considered that the compatibility with the resin (A) is improved, and even when the composition according to the present invention is stored over time, aggregation of the resin (B) can be suppressed, and the resin (B) can be homogeneously dispersed. It is considered that, as a result, the mass distribution of the resin (B) in the film obtained from the composition after storage over time can be made uniform, and furthermore, the number of defects in the obtained pattern can be reduced.

In particular, as described above, since a composition for forming a thick film generally has a high concentration of solid contents, aggregation of a plasticizer that may be included is likely to occur during storage of the composition over time. However, in the composition according to the present invention, presumably, aggregation of the resin (B) can be suppressed at an extremely high level as described above even at a high concentration of solid contents, and thus defects in a pattern after the lapse of time can be reduced.

The actinic ray-sensitive or radiation-sensitive resin composition according to the present invention is typically a resist composition (preferably a chemical amplification resist composition), and may be a positive resist composition or a negative resist composition. Furthermore, the actinic ray-sensitive or radiation-sensitive resin composition according to the present invention may be a resist composition for alkali development or a resist composition for organic solvent development.

### Resin (A) Including Repeating Unit (a1) Having Acid-Decomposable Group and Repeating Unit (a2) Having Aromatic Ring

The resin (A) including a repeating unit (a1) having an acid-decomposable group and a repeating unit (a2) having an aromatic ring (also simply referred to as a “resin (A)”) included in the composition according to the present invention will be described.

### Repeating Unit (a1) Having Acid-Decomposable Group

First, a repeating unit (a1) having an acid-decomposable group (hereinafter, also referred to as a “repeating unit (a1)” will be described.

The resin (A) has a repeating unit (a1) having an acid-decomposable group.

The acid-decomposable group refers to a group that is decomposed due to the action of an acid to generate a polar group. The acid-decomposable group preferably has a structure in which the polar group is protected with a group (leaving group) that leaves due to the action of an acid. That is, the resin (A) preferably has a repeating unit having a group that is decomposed due to the action of an acid to generate a polar group. The resin (A) is preferably a resin that undergoes an increase in polarity due to the action of an acid to have increased solubility in an alkali developer and decreased solubility in an organic solvent.

The polar group is preferably an alkali-soluble group. Examples thereof include acid groups such as a carboxyl group, a phenolic hydroxyl group, fluorinated alcohol groups, a sulfonic group, a sulfonamide group, a sulfonylimide group, (alkylsulfonyl) (alkylcarbonyl)methylene groups, (alkylsulfonyl) (alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxyl group.

The polar group is preferably a carboxyl group, a hydroxyl group, a fluorinated alcohol group (preferably a hexafluoroisopropanol group), or a sulfonic group.

Examples of the group (leaving group) that leaves due to the action of an acid include groups represented by Formulae (Y1) to (Y4).

—C(Rx₁)(Rx₂)(Rx₃) Formula(Y1)

—C(═O)OC(Rx₁)(Rx₂)(Rx₃) Formula(Y2)

—C(R₃₆)(R₃₇)(OR38)Formula(Y3)

—C(Rn)(H)(Ar) Formula(Y4)

In Formulae (Y1) and (Y2), Rx₁ to Rx₃ each independently represent an alkyl group (linear or branched) or a cycloalkyl group (monocyclic or polycyclic). Note that, when Rx₁ to Rx₃ are all alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two of Rx₁ to Rx₃ may be bonded together to form a monocycle or a polycycle.

The alkyl group in Rx₁ to Rx₃ is preferably an alkyl group having 1 to 4 carbon atoms such as a methyl group, an ethyl group, a n-propyl group, an isopropyl group, a n-butyl group, an isobutyl group, or a t-butyl group.

The cycloalkyl group in Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The cycloalkyl group formed by bonding two of Rx₁ to Rx₃ together is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, more preferably a monocyclic cycloalkyl group having 5 to 6 carbon atoms.

In the cycloalkyl group formed by bonding two of Rx₁ to Rx₃ together, for example, one of methylene groups forming the ring may be replaced by a heteroatom such as an oxygen atom, or a group having a heteroatom, such as a carbonyl group.

The group represented by Formula (Y1) or Formula (Y2) preferably has a form in which, for example, Rx₁ is a methyl group or an ethyl group, and Rx₂ and Rx₃ are bonded together to form the above-described cycloalkyl group.

In Formula (Y3), R₃₆ to R₃₈ each independently represent a hydrogen atom or a monovalent substituent. R₃₇ and R₃₈ may be bonded together to form a ring. Examples of the monovalent substituent include, but are not particularly limited to, alkyl groups, cycloalkyl groups, aryl groups, aralkyl groups, and alkenyl groups. It is also preferable that R₃₆ be a hydrogen atom.

Formula (Y3) preferably represents a group represented by Formula (Y3-1) below.

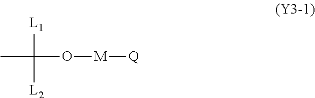

Here, L₁ and L₂ each independently represent a hydrogen atom, an alkyl group, a cycloalkyl group, an aryl group, or a group of a combination of the foregoing (for example, a group of a combination of an alkyl group and an aryl group).
M represents a single bond or a divalent linking group.
Q represents an alkyl group that may have a heteroatom, a cycloalkyl group that may have a heteroatom, an aryl group that may have a heteroatom, an amino group, an ammonium group, a mercapto group, a cyano group, an aldehyde group, or a group of a combination of the foregoing (for example, a group of a combination of an alkyl group and a cycloalkyl group).
In the alkyl group and the cycloalkyl group, for example, one of methylene groups may be replaced by a heteroatom such as an oxygen atom or a group having a heteroatom, such as a carbonyl group.

Note that one of L₁ and L₂ is preferably a hydrogen atom and the other is preferably an alkyl group, a cycloalkyl group, an aryl group, or a group that is a combination of an alkylene group and an aryl group.

At least two of Q, M, and L₁ may be bonded together to form a ring (preferably a five-membered or six-membered ring).

From the viewpoint of forming a finer pattern, L₂ is preferably a secondary or tertiary alkyl group, more preferably a tertiary alkyl group. Examples of the secondary alkyl group include an isopropyl group, a cyclohexyl group, and a norbornyl group. Examples of the tertiary alkyl group include a tert-butyl group and an adamantane ring group. In such forms, since Tg (glass transition temperature) and activation energy are high, the film hardness is ensured, and the occurrence of fogging can be suppressed.

In Formula (Y4), Ar represents an aromatic ring group. Rn represents an alkyl group, a cycloalkyl group, or an aryl group. Rn and Ar may be bonded together to form a non-aromatic ring. Ar is more preferably an aryl group.

The repeating unit having an acid-decomposable group is preferably at least one of a repeating unit represented by General formula (Aa1) below or a repeating unit represented by General formula (Aa2) below.

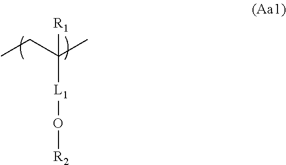

In General formula (Aa1), L₁ represents a divalent linking group, R₁ represents a hydrogen atom, a fluorine atom, an iodine atom, an alkyl group, or an aryl group, and R₂ represents a group that leaves due to the action of an acid.

L₁ represents a divalent linking group. Examples of the divalent linking group include —CO—, —O—, —S—, —SO—, —SO₂—, hydrocarbon groups (such as alkylene groups, cycloalkylene groups, alkenylene groups, and arylene groups), and linking groups provided by linking a plurality of the foregoing together. The hydrocarbon groups may have a substituent.

L₁ is preferably —CO—, an alkylene group, or an arylene group.

The arylene group is preferably an arylene group having 6 to 20 carbon atoms, more preferably an arylene group having 6 to 10 carbon atoms, still more preferably a phenylene group.

The alkylene group may be linear or branched. The number of carbon atoms of the alkylene group is not particularly limited, but is preferably 1 to 10, more preferably 1 to 3. The arylene group preferably has a fluorine atom or an iodine atom. The total number of fluorine atoms and iodine atoms included in the alkylene groups is not particularly limited, but is preferably 2 or more, more preferably 2 to 10, still more preferably 3 to 6.

R₁ represents a hydrogen atom, a fluorine atom, an iodine atom, an alkyl group, or an aryl group.

The alkyl group may be linear or branched. The number of carbon atoms of the alkyl group is not particularly limited, but is preferably 1 to 10, more preferably 1 to 3.

When the alkyl group has a fluorine atom or an iodine atom, the total number of fluorine atoms and iodine atoms included in the alkyl group is not particularly limited, but is preferably 1 or more, more preferably 1 to 5, still more preferably 1 to 3.

The alkyl group may have a heteroatom, such as an oxygen atom, other than a halogen atom.

R₂ represents a group (leaving group) that leaves due to the action of an acid.

Examples of the leaving group include the above-described groups represented by Formulae (Y1) to (Y4), and preferred ranges thereof are also the same as those described above.

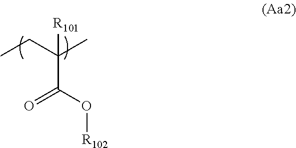

In General formula (Aa2), R₁₀₁ represents a hydrogen atom, a fluorine atom, an iodine atom, an alkyl group, or an aryl group, and R₁₀₂ represents a group that leaves due to the action of an acid.

R₁₀₁ represents a hydrogen atom, a fluorine atom, an iodine atom, an alkyl group, or an aryl group.

The alkyl group may be linear or branched. The number of carbon atoms of the alkyl group is not particularly limited, but is preferably 1 to 10, more preferably 1 to 3.

When the alkyl group has a fluorine atom or an iodine atom, the total number of fluorine atoms and iodine atoms included in the alkyl group is not particularly limited, but is preferably 1 or more, more preferably 1 to 5, still more preferably 1 to 3.

The alkyl group may have a heteroatom, such as an oxygen atom, other than a halogen atom.

R₁₀₂ represents a group (leaving group) that leaves due to the action of an acid.

Examples of the leaving group include the above-described groups represented by Formulae (Y1) to (Y4), and preferred ranges thereof are also the same as those described above.

Because of a high dissolution contrast before and after deprotection, the repeating unit having an acid-decomposable group and included in the resin (A) is preferably a repeating unit represented by General formula (Aa2) above, more preferably a repeating unit represented by General formula (AI) below.

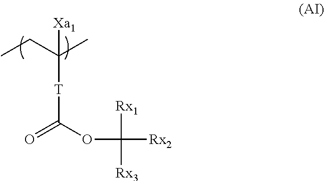

In General formula (AI),

Xa₁ represents a hydrogen atom or an alkyl group.

T represents a single bond or a divalent linking group.

Rx₁ to Rx₃ each independently represent an alkyl group (linear or branched) or a cycloalkyl group (monocyclic or polycyclic). Note that, when Rx₁ to Rx₃ are all alkyl groups (linear or branched), at least two of Rx₁ to Rx₃ are preferably methyl groups.

Two of Rx₁ to Rx₃ May be Bonded Together to Form a Cycloalkyl Group (Monocyclic or Polycyclic).

The alkyl group represented by Xa₁ may have a substituent. Examples of the alkyl group represented by Xa₁ include a methyl group and a group represented by —CH₂—R₁₁. R₁₁ represents a halogen atom (such as a fluorine atom), a hydroxyl group, or a monovalent substituent, and examples thereof include alkyl groups having 5 or less carbon atoms and optionally substituted with a halogen atom, acyl groups having 5 or less carbon atoms and optionally substituted with a halogen atom, and alkoxy groups having 5 or less carbon atoms and optionally substituted with a halogen atom. R₁₁ is preferably an alkyl group having 3 or less carbon atoms, more preferably a methyl group. Xa₁ is preferably a hydrogen atom, a methyl group, a trifluoromethyl group, or a hydroxymethyl group.

The divalent linking group represented by T may have a substituent.

Examples of the divalent linking group represented by T include alkylene groups, aromatic ring groups, a —COO—Rt-group, and an —O—Rt-group. In the formulae, Rt represents an alkylene group or a cycloalkylene group.

T is preferably a single bond or a —COO—Rt-group. When T represents a —COO-Rt-group, Rt is preferably an alkylene group having 1 to 5 carbon atoms, more preferably a —CH₂-group, a —(CH₂)₂-group, or a —(CH₂)₃-group.

The alkyl group in Rx₁ to Rx₃ is preferably an alkyl group having 1 to 4 carbon atoms such as a methyl group, an ethyl group, a n-propyl group, an isopropyl group, a n-butyl group, an isobutyl group, or a t-butyl group.

The cycloalkyl group in Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The cycloalkyl group formed by bonding two of Rx₁ to Rx₃ together is preferably a monocyclic cycloalkyl group such as a cyclopentyl group or a cyclohexyl group, or preferably a polycyclic cycloalkyl group such as a norbornyl group, a tetracyclodecanyl group, a tetracyclododecanyl group, or an adamantyl group. Of these, a monocyclic cycloalkyl group having 5 to 6 carbon atoms is preferred.

In the cycloalkyl group formed by bonding two of Rx₁ to Rx₃ together, for example, one of methylene groups forming the ring may be replaced by a heteroatom such as an oxygen atom, or a group having a heteroatom, such as a carbonyl group.

The repeating unit represented by General formula (AI) preferably has a form in which, for example, Rx₁ is a methyl group or an ethyl group, and Rx₂ and Rx₃ are bonded together to form the above-described cycloalkyl group.

When any of the above-described groups has a substituent, examples of the substituent include alkyl groups (having 1 to 4 carbon atoms), halogen atoms, a hydroxyl group, alkoxy groups (having 1 to 4 carbon atoms), a carboxyl group, and alkoxycarbonyl groups (having 2 to 6 carbon atoms). The number of carbon atoms in the substituent is preferably 8 or less.

The repeating unit represented by General formula (AI) is preferably an acid-decomposable tertiary alkyl (meth)acrylate-based repeating unit (a repeating unit in which Xa₁ represents a hydrogen atom or a methyl group, and T represents a single bond).

It is also preferred that the resin (A) have at least one repeating unit selected from the group consisting of repeating units represented by General formulae (A-VIII) to (A-XII) below as the repeating unit having an acid-decomposable group.

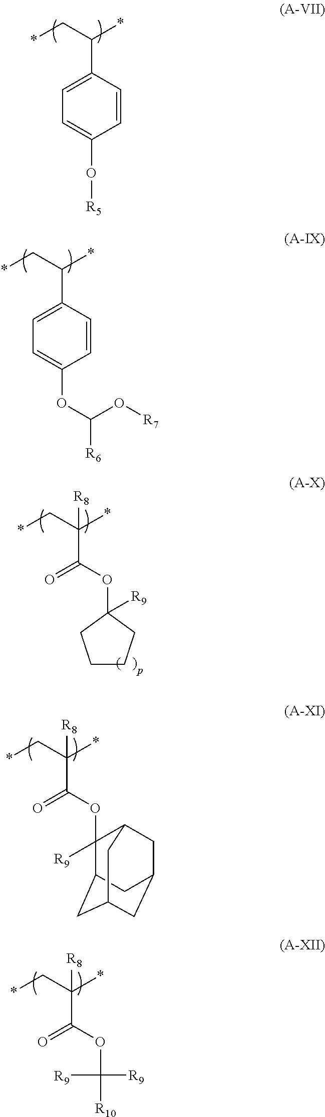

In General formula (A-VIII), R₅ represents a tert-butyl group, a 1,1′-dimethylpropyl group, or a —CO—O-(tert-butyl) group.

In General formula (A-IX), R₆ and R₇ each independently represent a monovalent substituent. Examples of the monovalent substituent include alkyl groups, cycloalkyl groups, aryl groups, aralkyl groups, and alkenyl groups.

In General formula (A-X), p represents 1 or 2.

In General formulae (A-X) to (A-XII), R₈ represents a hydrogen atom or an alkyl group having 1 to 3 carbon atoms, and R₉ represents an alkyl group having 1 to 3 carbon atoms.

In General formula (A-XII), R₁₀ represents an alkyl group having 1 to 3 carbon atoms or an adamantyl group.

The resin (A) may have only one repeating unit having an acid-decomposable group or two or more repeating units having an acid-decomposable group.

The content of the repeating unit having an acid-decomposable group in the resin (A) (in the case where the resin (A) has two or more repeating units having an acid-decomposable group, the total content thereof) is, on a molar basis, preferably 70 mol % or less, more preferably 50 mol % or less, still more preferably 30 mol % or less, particularly preferably 10 mol % or more and 30 mol % or less, most preferably 20 mol % or more and 30 mol % or less relative to all the repeating units in the resin (A).

The resin (A) may have other repeating units in addition to the repeating unit having an acid-decomposable group.

### Repeating Unit (a2) Having Aromatic Ring

Next, a repeating unit (a2) having an aromatic ring (hereinafter, also referred to as a “repeating unit (a2)” will be described.

The aromatic ring may be an aromatic hydrocarbon ring or an aromatic heterocycle.

The aromatic hydrocarbon ring may be monocyclic or polycyclic, examples thereof include aromatic hydrocarbon rings having 6 to 20 carbon atoms, and specific examples thereof include a benzene ring, a naphthalene ring, and an anthracene ring.

The aromatic heterocycle may be monocyclic or polycyclic, and examples thereof include a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring.

The number of carbon atoms in the aromatic heterocycle is preferably 5 to 14, more preferably 5 to 10.

In the repeating unit (a1) having an acid-decomposable group, those having an aromatic ring are also encompassed by the repeating unit (a2) having an aromatic ring.

The repeating unit (a2) is preferably a repeating unit represented by General formula (B) below.

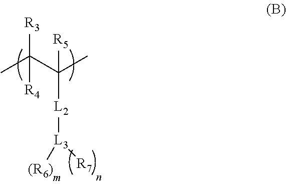

R₃ represents a hydrogen atom or a monovalent substituent. The monovalent substituent may have a fluorine atom or an iodine atom. The monovalent substituent is preferably a group represented by -L₄₀-R₈. L₄₀ represents a single bond or an ester group. R₈ may be an alkyl group that may have a fluorine atom or an iodine atom, a cycloalkyl group that may have a fluorine atom or an iodine atom, an aryl group that may have a fluorine atom or an iodine atom, or a group of a combination of the foregoing.

R₄ and R₅ each independently represent a hydrogen atom, a fluorine atom, an iodine atom, or an alkyl group that may have a fluorine atom or an iodine atom.

L₂ represents a single bond or an ester group.

L₃ represents an (n+m+1)-valent aromatic hydrocarbon ring group. The aromatic hydrocarbon ring group may be a benzene ring group or a naphthalene ring group.

R₆ represents a hydroxyl group or a fluorinated alcohol group (preferably a hexafluoroisopropanol group). When R₆ is a hydroxyl group, L₃ is preferably an (n+m+1)-valent aromatic hydrocarbon ring group.

R₇ represents a halogen atom. The halogen atom may be a fluorine atom, a chlorine atom, a bromine atom, or an iodine atom.

m represents an integer of 1 or more. m is preferably an integer of 1 to 3, more preferably an integer of 1 to 2.

n represents 0 or an integer of 1 or more. n is preferably an integer of 1 to 4.

Note that (n+m+1) is preferably an integer of 1 to 5.

The repeating unit (a2) is also preferably a repeating unit represented by General formula (I) below.

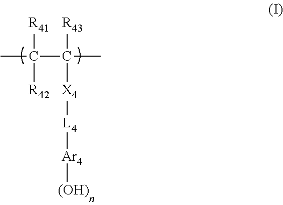

In General formula (I),

R₄₁, R₄₂ and R₄₃ each independently represent a hydrogen atom, an alkyl group, a cycloalkyl group, a halogen atom, a cyano group, or an alkoxycarbonyl group. However, R₄₂ may be bonded to Ar₄ to form a ring, and in such a case, R₄₂ represents a single bond or an alkylene group.

X₄ represents a single bond, —COO— or —CONR₆₄—, and R₆₄ represents a hydrogen atom or an alkyl group.

L₄ represents a single bond or an alkylene group.

Ar₄ represents an (n+1)-valent aromatic ring group, and when Ar₄ is bonded to R₄₂ to form a ring, Ar₄ represents an (n+2)-valent aromatic ring group.

n represents an integer of 1 to 5.

In R₄₁, R₄₂, and R₄₃ in General formula (I), the alkyl groups are preferably alkyl groups having 20 or less carbon atoms, such as a methyl group, an ethyl group, a propyl group, an isopropyl group, a n-butyl group, a sec-butyl group, a hexyl group, a 2-ethylhexyl group, an octyl group, and a dodecyl group, more preferably alkyl groups having 8 or less carbon atoms, still more preferably alkyl groups having 3 or less carbon atoms.

In R₄₁, R₄₂, and R₄₃ in General formula (I), the cycloalkyl groups may be monocyclic or polycyclic. In particular, monocyclic cycloalkyl groups having 3 to 8 carbon atoms, such as a cyclopropyl group, a cyclopentyl group, and a cyclohexyl group, are preferred.

Examples of the halogen atoms in R₄₁, R₄₂, and R₄₃ in General formula (I) include a fluorine atom, a chlorine atom, a bromine atom, and an iodine atom, and a fluorine atom is preferred.

The alkyl groups included in the alkoxycarbonyl groups in R₄₁, R₄₂, and R₄₃ in General formula (I) are preferably the same as the foregoing alkyl groups in R₄₁, R₄₂, and R₄₃.

Ar₄ represents an (n+1)-valent aromatic ring group. The divalent aromatic ring group in the case where n is 1 may have a substituent and is preferably, for example, an arylene group having 6 to 18 carbon atoms, such as a phenylene group, a tolylene group, a naphthylene group, or an anthracenylene group, or an aromatic ring group including a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring.

Specific examples of the (n+1)-valent aromatic ring group in the case where n is an integer of 2 or more include groups provided by removing any (n−1) hydrogen atoms from the foregoing specific examples of the divalent aromatic ring group. The (n+1)-valent aromatic ring group may further have a substituent.

Examples of substituents that the foregoing alkyl groups, cycloalkyl groups, alkoxycarbonyl groups, alkylene groups, and the (n+1)-valent aromatic ring groups may have include the alkyl groups described in R₄₁, R₄₂, and R₄₃ in General formula (I); alkoxy groups such as a methoxy group, an ethoxy group, a hydroxyethoxy group, a propoxy group, a hydroxypropoxy group, and a butoxy group; aryl groups such as a phenyl group.

Examples of the alkyl group of R₆₄ in —CONR₆₄— (where R₆₄ represents a hydrogen atom or an alkyl group) represented by X₄ include alkyl groups having 20 or less carbon atoms, such as a methyl group, an ethyl group, a propyl group, an isopropyl group, a n-butyl group, a sec-butyl group, a hexyl group, a 2-ethylhexyl group, an octyl group, and a dodecyl group. Of these, alkyl groups having 8 or less carbon atoms are preferred.

X₄ is preferably a single bond, —COO—, or —CONH—, more preferably a single bond or —COO—.

The alkylene group in L₄ is preferably an alkylene group having 1 to 8 carbon atoms, such as a methylene group, an ethylene group, a propylene group, a butylene group, a hexylene group, or an octylene group.

Ar₄ is preferably an aromatic ring group having 6 to 18 carbon atoms, more preferably a benzene ring group, a naphthalene ring group, or a biphenylene ring group.

Specific examples of the repeating unit (a2) are shown below; however, the present invention is not limited thereto. In the formulae, a represents 0, 1, 2 or 3.

When a represents 1, 2 or 3, the following specific examples are specific examples of the repeating unit represented by General formula (I).

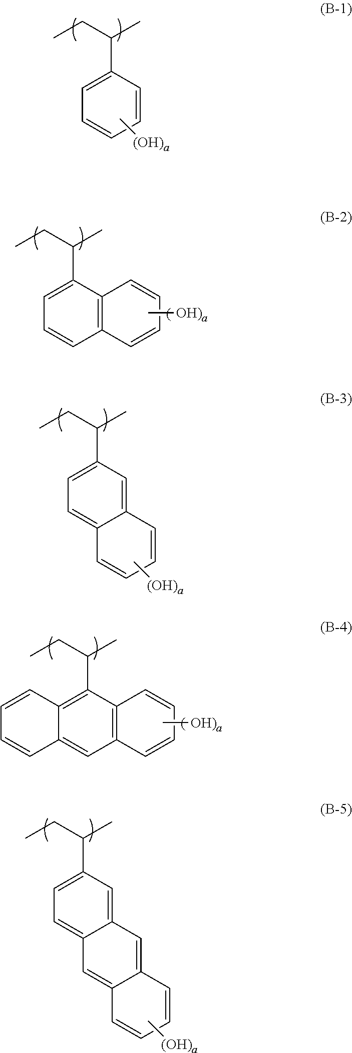

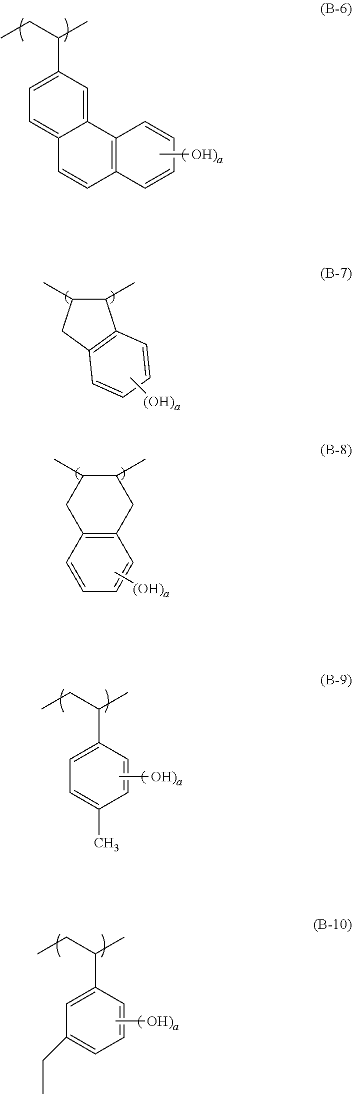

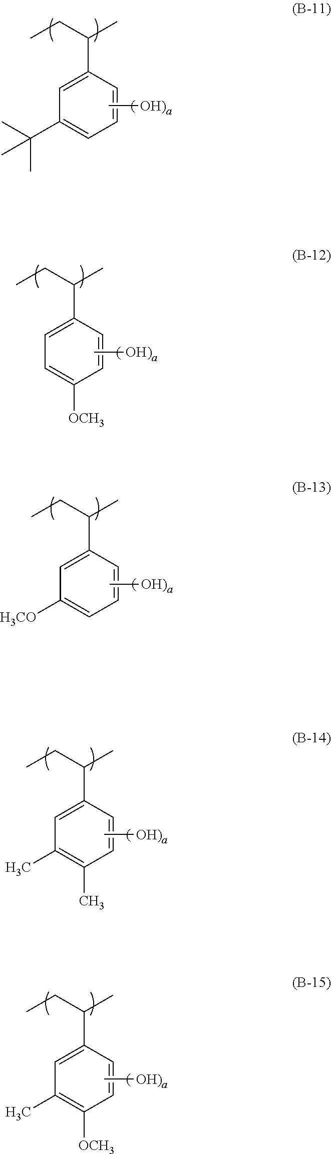

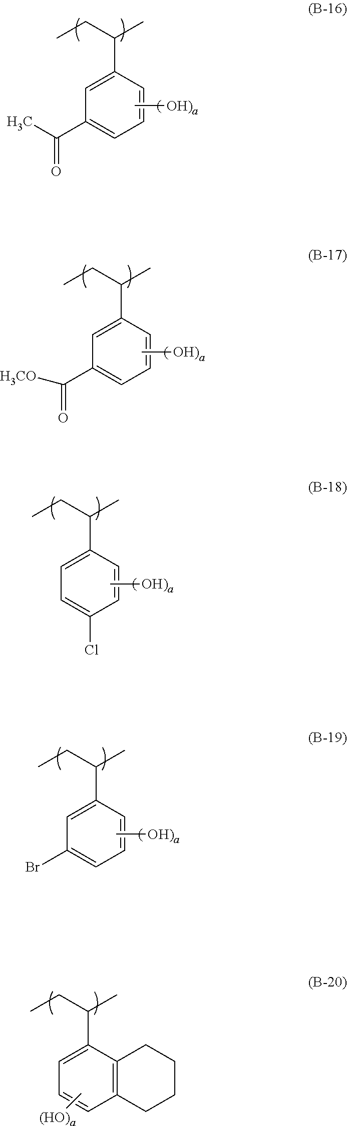

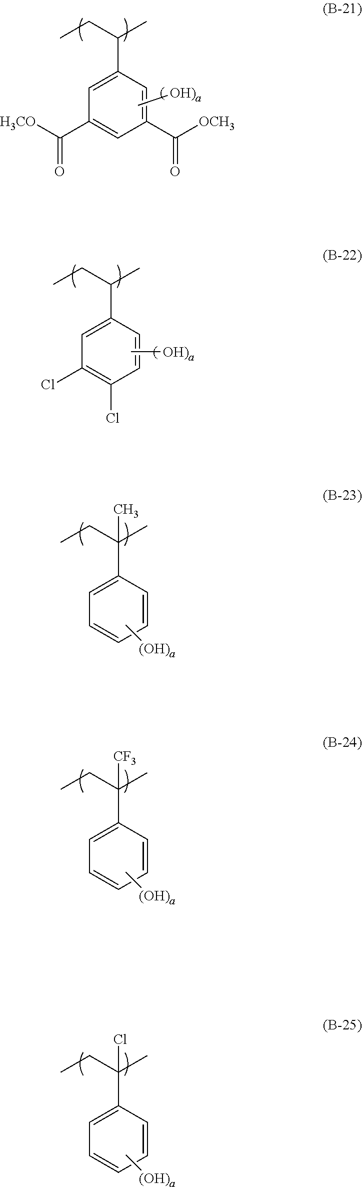

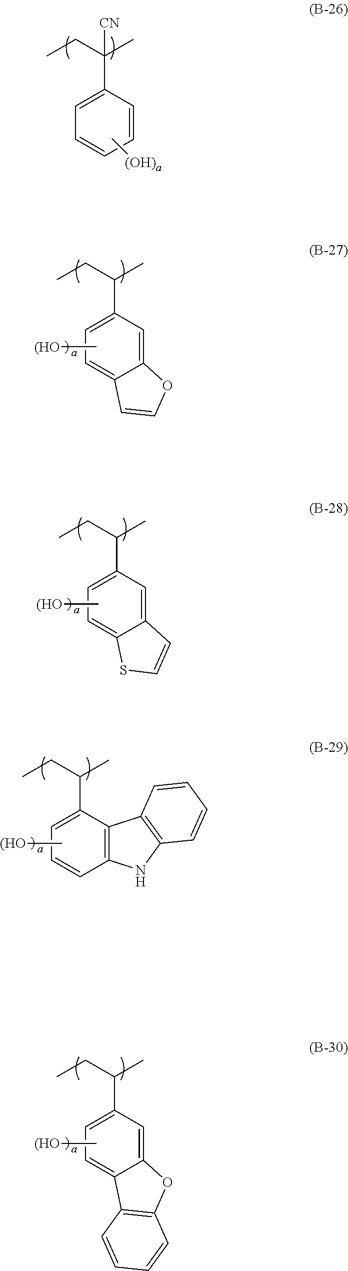

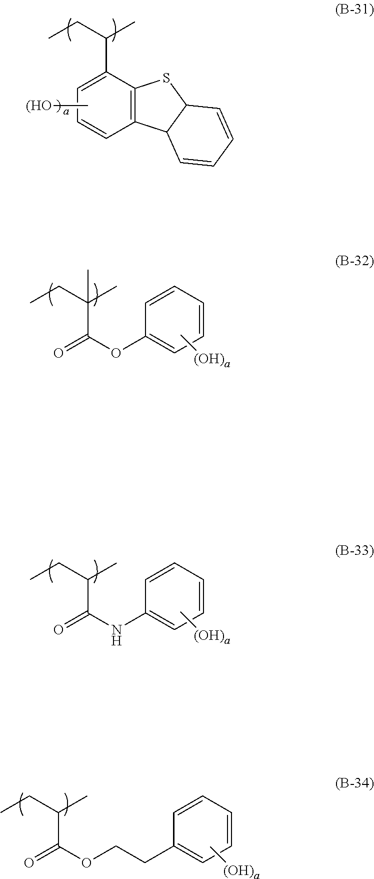

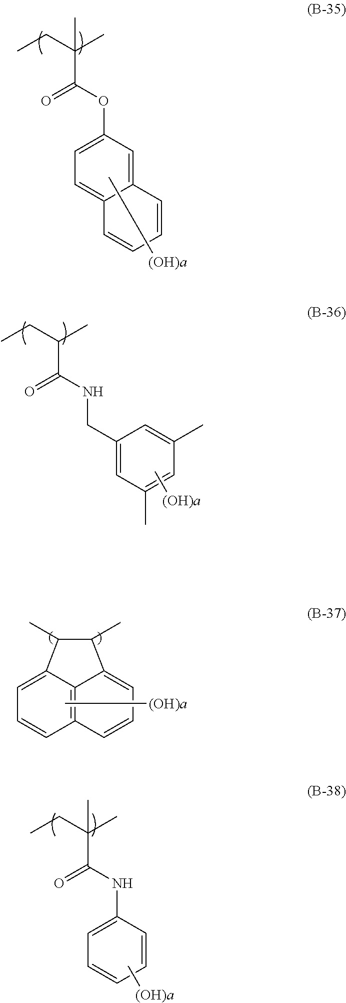

The resin (A) may have only one repeating unit (a2) or two or more repeating units (a2).

The content of the repeating unit (a2) in the resin (A) (in the case where the resin (A) has two or more repeating units (a2), the total content thereof) is, on a molar basis, preferably 90 mol % or less, more preferably 80 mol % or less, still more preferably 70 mol % or less, particularly preferably 50 mol % or more and 85 mol % or less, most preferably 55 mol % or more and 80 mol % or less relative to all the repeating units in the resin (A).

The total of the content of the repeating unit (a1) in the resin (A) (in the case where the resin (A) has two or more repeating units (a1), the total content thereof) and the content of the repeating unit (a2) in the resin (A) (in the case where the resin (A) has two or more repeating units (a2), the total content thereof) is, on a molar basis, preferably 80 mol % or more, more preferably 85 mol % or more relative to all the repeating units in the resin (A).

In a preferred embodiment, the resin (A) contains only the repeating unit (a1) and the repeating unit (a2).

The resin (A) may have other repeating units in addition to the repeating unit (a1) and the repeating unit (a2).

Hereinafter, the other repeating units will be described.

Repeating Unit (A-2) Having at Least One Selected from the Group Consisting of Lactone Structure, Sultone Structure, Carbonate Structure, and Hydroxyadamantane Structure

The resin (A) may have a repeating unit (A-2) having at least one selected from the group consisting of a lactone structure, a carbonate structure, a sultone structure, and a hydroxyadamantane structure.

The lactone structure or the sultone structure in the repeating unit having a lactone structure or a sultone structure is not particularly limited, but is preferably a five- to seven-membered lactone structure or a five to seven-membered sultone structure, more preferably a five to seven-membered lactone structure to which another ring structure is fused so as to form a bicyclo structure or a spiro structure, or a five to seven-membered sultone structure to which another ring structure is fused so as to form a bicyclo structure or a spiro structure.

Examples of the repeating unit having a lactone structure or a sultone structure include the repeating units described in paragraphs 0094 to 0107 of WO2016/136354A.

The resin (A) may have a repeating unit having a carbonate structure. The carbonate structure is preferably a cyclic carbonate ester structure.

Examples of the repeating unit having a carbonate structure include the repeating units described in paragraphs 0106 to 0108 of WO2019/054311A.

The resin (A) may have a repeating unit having a hydroxyadamantane structure. The repeating unit having a hydroxyadamantane structure may be a repeating unit represented by General formula (AIIa) below.

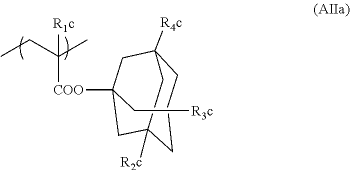

In General formula (Alla), R₁c represents a hydrogen atom, a methyl group, a trifluoromethyl group, or a hydroxymethyl group. R₂c to R₄c each independently represent a hydrogen atom or a hydroxyl group. However, at least one of R₂c to R₄c represents a hydroxyl group. Preferably, one or two of R₂c to R₄c are each a hydroxyl group, and the remainder is a hydrogen atom.

### Repeating Unit Having Fluorine Atom or Iodine Atom

The resin (A) may have a repeating unit having a fluorine atom or an iodine atom.

Examples of the repeating unit having a fluorine atom or an iodine atom include the repeating units described in paragraphs 0076 to 0081 of JP2019-045864A.

### Repeating Unit Having Photoacid Generating Group

The resin (A) may have, as a repeating unit other than the foregoing, a repeating unit having a photoacid generating group (a group that generates an acid upon irradiation with an actinic ray or a radiation).

### Examples of the Repeating Unit Having a Photoacid Generating Group Include the Repeating Units Described in Paragraphs 0092 to 0096 of JP2019-045864A.

### Repeating Unit Having Alkali-Soluble Group

The resin (A) may have a repeating unit having an alkali-soluble group.

The alkali-soluble group may be a carboxyl group, a sulfonamide group, a sulfonylimide group, a bissulfonylimide group, or an aliphatic alcohol group substituted with an electron-withdrawing group at the α-position (for example, a hexafluoroisopropanol group), and is preferably a carboxyl group. When the resin (A) has a repeating unit having an alkali-soluble group, the resolution is increased in contact-hole applications.

The repeating unit having an alkali-soluble group may be a repeating unit in which an alkali-soluble group is directly bonded to the main chain of a resin, such as a repeating unit derived from acrylic acid or methacrylic acid, or a repeating unit in which an alkali-soluble group is bonded to the main chain of a resin through a linking group. The linking group may have a monocyclic or polycyclic cyclic hydrocarbon structure.

The repeating unit having an alkali-soluble group is preferably a repeating unit derived from acrylic acid or methacrylic acid.

### Repeating Unit Having Neither Acid-Decomposable Group Nor Polar Group

The resin (A) may further have a repeating unit having neither an acid-decomposable group nor a polar group. The repeating unit having neither an acid-decomposable group nor a polar group preferably has an alicyclic hydrocarbon structure.

Examples of the repeating unit having neither an acid-decomposable group nor a polar group include the repeating units described in paragraphs 0236 to 0237 of US2016/0026083A and the repeating units described in paragraph 0433 of US2016/0070167A.

The resin (A) may have, in addition to the foregoing repeating structural units, various repeating structural units for the purpose of adjusting, for example, dry etching resistance, suitability for a standard developer, substrate adhesiveness, resist profile, resolving power, heat resistance, and sensitivity.

The resin (A) can be synthesized in accordance with an ordinary method (for example, radical polymerization).

The resin (A) has a weight-average molecular weight (Mw_{A}) of preferably 1,000 to 200,000, more preferably 3,000 to 50,000, still more preferably 5,000 to 30,000. Note that Mw_{A} is a polystyrene-equivalent value measured by the GPC method described above.

The molecular weight distribution (Mw_{A}/Mn_{A}) of the resin (A), which is a value obtained by dividing Mw_{A} by the number-average molecular weight Mn_{A} of the resin (A), is usually 1.00 to 5.00, preferably 1.00 to 3.00, more preferably 1.10 to 2.00. The smaller the molecular weight distribution, the better the resolution and the resist profile, the smoother the sidewalls of the pattern, and the better the roughness performance.

The content (S_{A}) of the resin (A) relative to the total solid content in the composition according to the present invention is, on a mass basis, preferably 40 to 95 mass %, more preferably 60 to 95 mass %.

Such resins (A) may be used alone or in combination of two or more thereof. When two or more resins (A) are used in combination, the total amount thereof is preferably within the range described above.

In the present specification, the solid contents mean components other than solvents. Even if the components are in the form of liquid, the components are regarded as solid contents. The total solid content means the sum of all solid contents.

### Resin (B) Including Repeating Unit (b1) Represented by General Formula (1)

The composition according to the present invention contains a resin (B) including a repeating unit (b1) represented by General formula (1) (hereinafter, also referred to as a resin (B)).

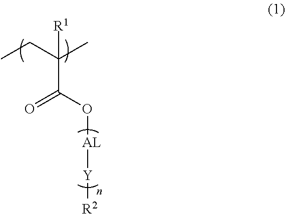

In General formula (1),

R¹ and R² each independently represent a hydrogen atom or a hydrocarbon group.
AL represents a linear or branched alkylene group. When n represents an integer of 2 or more, a plurality of AL's may be the same or different from each other. However, each AL does not include an acid-decomposable group.
Y represents —O—, —S—, —COO—, or —OCO—. When n represents an integer of 2 or more, a plurality of Y's may be the same or different from each other.
n represents an integer of 1 or more.

The hydrocarbon group in R¹ and R² is not particularly limited and may be an alkyl group, a cycloalkyl group, or an aromatic ring group.

The alkyl group may be linear or branched. The number of carbon atoms of the alkyl group is not particularly limited but is preferably 1 to 10, more preferably 1 to 3.

The cycloalkyl group may be monocyclic or polycyclic. The number of carbon atoms of the cycloalkyl group is not particularly limited but is preferably 3 to 15, more preferably 3 to 10.

The aromatic ring in the aromatic ring group may be an aromatic hydrocarbon ring or an aromatic heterocycle.

The aromatic hydrocarbon ring may be monocyclic or polycyclic, examples thereof include aromatic hydrocarbon rings having 6 to 20 carbon atoms, and specific examples thereof include a benzene ring, a naphthalene ring, and an anthracene ring.

The aromatic heterocycle may be monocyclic or polycyclic, and examples thereof include a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring.

The number of carbon atoms in the aromatic heterocycle is preferably 5 to 14, more preferably 5 to 10.

The alkyl group, the cycloalkyl group, and the aromatic ring group may have a substituent.

R₁ preferably represents a hydrogen atom or an alkyl group, more preferably represents a hydrogen atom or a methyl group, and still more preferably represents a hydrogen atom.

R₂ preferably represents a hydrogen atom or an alkyl group, and more preferably represents a hydrogen atom or an alkyl group having 1 to 6 carbon atoms.

AL represents a linear or branched alkylene group.

The linear or branched alkylene group is not particularly limited, and may be, for example, a linear or branched alkylene group having 1 to 10 carbon atoms. The number of carbon atoms of the linear or branched alkylene group is preferably 1 to 5, more preferably 1 to 2.

The linear or branched alkylene group may have a substituent. AL does not have an acid-decomposable group. The acid-decomposable group is the same as the above-described acid-decomposable group in the repeating unit (a1) of the resin (A).

Y represents —O—, —S—, —COO—, or —OCO—.

Y preferably represents —O—, —S—, or —COO— and more preferably represents —O— or —S—.

n represents an integer of 1 or more.

The upper limit value of n is not particularly limited, but is usually 5 or less.

n preferably represents an integer of 1 to 3, and more preferably represents 1 or 2.

In General formula (1), AL is preferably an ethylene group, and Y is preferably —O—.

Having such an ethylene ether moiety is preferred because the compatibility with the resin (A) is further improved.

Specific examples of the monomer corresponding to the repeating unit (b1) are shown below; however, the present invention is not limited thereto.

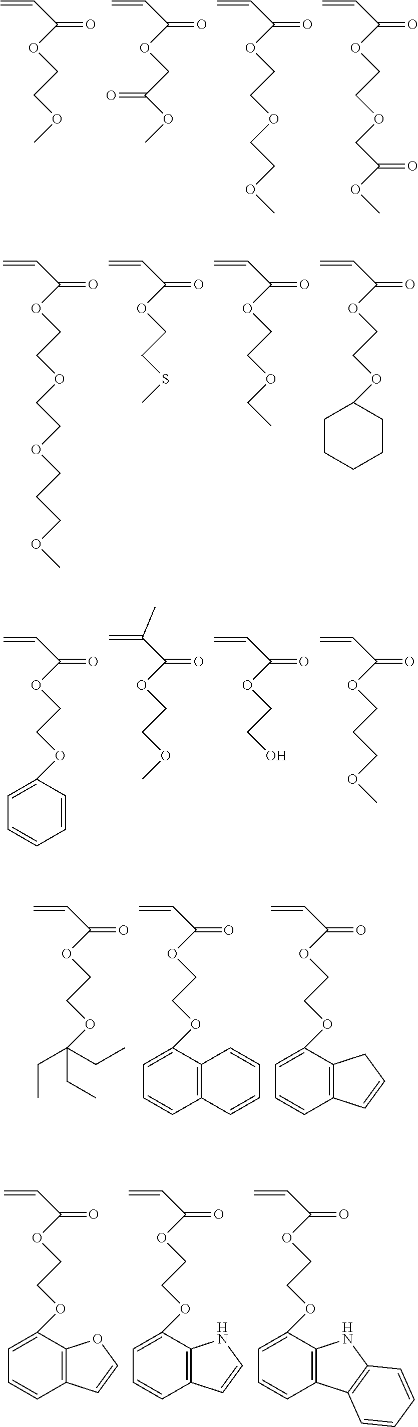

The content of the repeating unit (b1) in the resin (B) (in the case where the resin (B) has two or more repeating units (b1), the total content thereof) is, on a molar basis, preferably 95 mol % or less, more preferably 80 mol % or less, still more preferably 70 mol % or less relative to all the repeating units in the resin (B).

The content of the repeating unit (b1) in the resin (B) (in the case where the resin (B) has two or more repeating units (b1), the total content thereof) is, on a molar basis, preferably 20 mol % or more, more preferably 30 mol % or more, still more preferably 40 mol % or more relative to all the repeating units in the resin (B).

### Repeating Unit (b2) Having Carboxyl Group or Hydroxyl Group

The resin (B) preferably includes a repeating unit (b2) having a carboxyl group or a hydroxyl group (also simply referred to as a repeating unit (b2)). The resin (B) preferably has a repeating unit having a carboxylic group or a hydroxyl group because the compatibility with the resin (A) can be appropriately adjusted.

When the repeating unit (b1) has a carboxyl group or a hydroxyl group, the repeating unit (b1) is encompassed by the repeating unit (b2).

The repeating unit (b2) is preferably a repeating unit represented by General formula (2) below.

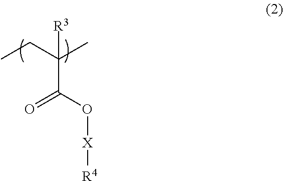

In General formula (2),

R³ represents a hydrogen atom or an alkyl group.

X represents a single bond or *-linear or branched alkylene group —O—*

R⁴ represent a hydrogen atom.

*represents a bonding site.

The alkyl group in R³ may be linear or branched. The number of carbon atoms of the alkyl group is not particularly limited, but is preferably 1 to 3, more preferably 1 to 2.

The linear or branched alkylene group in X is not particularly limited, and may be, for example, a linear or branched alkylene group having 1 to 10 carbon atoms. The number of carbon atoms of the linear or branched alkylene group is preferably 1 to 5, more preferably 1 to 2.

The linear or branched alkylene group may have a substituent. Preferably, X does not have an acid-decomposable group. The acid-decomposable group is the same as the above-described acid-decomposable group in the repeating unit (a1) of the resin (A).

The content of the repeating unit (b2) in the resin (B) (in the case where the resin (B) has two or more repeating units (b2), the total content thereof) is, on a molar basis, preferably 30 mol % or less, more preferably 25 mol % or less, still more preferably 20 mol % or less relative to all the repeating units in the resin (B).

The content of the repeating unit (b2) in the resin (B) (in the case where the resin (B) has two or more repeating units (b2), the total content thereof) is, on a molar basis, preferably 5 mol % or more, more preferably 10 mol % or more, still more preferably 15 mol % or more relative to all the repeating units in the resin (B).

The resin (B) may have other repeating units in addition to the repeating unit (b1) (and the repeating unit (b2) in the case where the resin (B) has the repeating unit (b2)).

Hereinafter, the other repeating units will be described.

The resin (B) preferably has a repeating unit represented by General formula (3) below (hereinafter, also referred to as a repeating unit (3)).

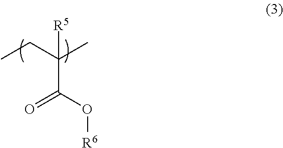

In General formula (3),

R⁵ represents a hydrogen atom or an alkyl group.

R⁶ represents a hydrocarbon group.

The alkyl group in R⁵ may be linear or branched. The number of carbon atoms of the alkyl group is not particularly limited, but is preferably 1 to 3, more preferably 1 to 2.

R⁵ preferably represents a hydrogen atom or a methyl group and more preferably represents a hydrogen atom.

The hydrocarbon group in R⁶ is not particularly limited, and may be, for example, an alkyl group, a cycloalkyl group, or an aromatic ring group.

The alkyl group may be linear or branched. The number of carbon atoms of the alkyl group is not particularly limited, but is preferably 1 to 10, more preferably 1 to 3.

The cycloalkyl group may be monocyclic or polycyclic. The number of carbon atoms of the cycloalkyl group is not particularly limited, but is preferably 3 to 15, more preferably 3 to 10.

The aromatic ring in the aromatic ring group may be an aromatic hydrocarbon ring or an aromatic heterocycle.

The aromatic hydrocarbon ring may be monocyclic or polycyclic, examples thereof include aromatic hydrocarbon rings having 6 to 20 carbon atoms, and specific examples thereof include a benzene ring, a naphthalene ring, and an anthracene ring.

The aromatic heterocycle may be monocyclic or polycyclic, and examples thereof include a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring.

The number of carbon atoms in the aromatic heterocycle is preferably 5 to 14, more preferably 5 to 10.

The alkyl group, the cycloalkyl group, and the aromatic ring group may have a substituent.

General formula (3) may or may not have an acid-decomposable group, but preferably does not have an acid-decomposable group.

Specific examples of the monomer corresponding to the repeating unit (3) are shown below; however, the present invention is not limited thereto.

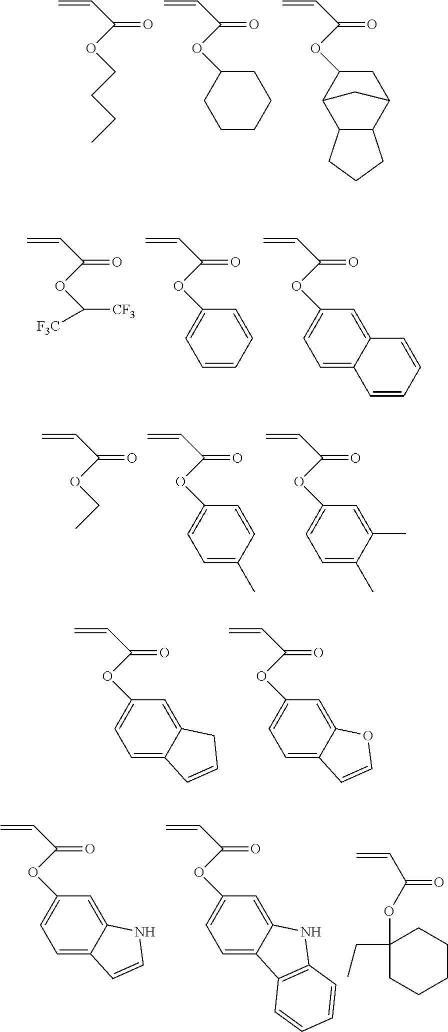

The content of the repeating unit (3) in the resin (B) (in the case where the resin (B) has two or more repeating units (3), the total content thereof) is, on a molar basis, preferably 70 mol % or less, more preferably 60 mol % or less, still more preferably 50 mol % or less relative to all the repeating units in the resin (B).

The content of the repeating unit (3) in the resin (B) (in the case where the resin (B) has two or more repeating units (3), the total content thereof) is, on a molar basis, preferably 20 mol % or more, more preferably 30 mol % or more, still more preferably 40 mol % or more relative to all the repeating units in the resin (B).

The content of a repeating unit having an acid-decomposable group and included in the resin (B) is 5 mol % or less relative to all the repeating units in the resin (B).

Examples of the repeating unit having an acid-decomposable group include the same repeating units as those having an acid-decomposable group in the resin (A).

The content of the repeating unit having an acid-decomposable group and included in the resin (B) is preferably 4 mol % or less, more preferably 3 mol % or less relative to all the repeating units in the resin (B).

The resin (B) has a dispersity of less than 3.0.

The dispersity of the resin (B) is a molecular weight distribution (Mw_{B}/Mn_{B}) of the resin (B), which is a value obtained by dividing the weight-average molecular weight Mw_{B} of the resin (B) by the number-average molecular weight (Mn_{B}) of the resin (B).

The resin (B) included in the composition according to the present invention is used as a plasticizer. When the dispersity of the resin (B) is less than 3.0, aggregation of the resin (B) can be suppressed during storage of the composition according to the present invention over time, and the mass distribution of the resin (B) in the film to be obtained can be made uniform. It is considered that, therefore, the number of defects in the obtained pattern can be reduced.

The dispersity of the resin (B) can be determined by the method described above.

The dispersity of the resin (B) is preferably 2.5 or less, more preferably 2.0 or less, still more preferably 1.8 or less.

The dispersity of the resin (B) is preferably 1.1 or more, more preferably 1.2 or more.

The method for adjusting the dispersity of the resin (B) to less than 3.0 is not particularly limited, and an example thereof may include appropriately selecting a purification step after the synthesis of the resin (B).

Specifically, for example, the dispersity of the resin (B) can be adjusted to less than 3.0 by appropriately selecting a solvent after the synthesis of the resin (B) and adjusting the number of times of reprecipitation.

In general, as the number of times of reprecipitation increases, the dispersity of the resin (B) tends to decrease.

The resin (B) can be synthesized in accordance with an ordinary method (for example, radical polymerization).

In a preferred embodiment, the dispersity of the resin (B) can be adjusted to less than 3.0 by removing low-molecular-weight components through purification by solvent fractionation. First, purification by solvent fractionation will be described. Purification by solvent fractionation can be performed by applying a usual method such as a purification method in a solution state, e.g., a liquid-liquid extraction method in which residual monomers and oligomer components are removed by washing with water or a combination of appropriate solvents, or ultrafiltration in which only components having a specific molecular weight or less are extracted and removed, or a purification method in a solid state, e.g., a reprecipitation method in which a resin solution is added dropwise to a poor solvent to solidify a resin in the poor solvent, thereby removing residual monomers and the like, or a method in which a filtered resin slurry is washed with a poor solvent.

For example, after completion of radical polymerization reaction, a solvent in which the resin is sparingly soluble or insoluble (poor solvent) is brought into contact with the reaction solution in an amount of less than 5 times, preferably 4.5 to 0.5 times, more preferably 3 to 0.5 times, still more preferably 1 to 0.5 times the volume of the reaction solution to precipitate the resin as a solid.

The solvent (precipitation or reprecipitation solvent) used in the precipitation or reprecipitation operation from the resin (polymer) solution may be a poor solvent for the polymer, and can be appropriately selected from the group consisting of, depending on the type of resin, for example, hydrocarbons (such as aliphatic hydrocarbons, e.g., pentane, hexane, heptane, and octane; alicyclic hydrocarbons, e.g., cyclohexane and methylcyclohexane; and aromatic hydrocarbons, e.g., benzene, toluene, and xylene), halogenated hydrocarbons (such as halogenated aliphatic hydrocarbons, e.g., methylene chloride, chloroform, and carbon tetrachloride; and halogenated aromatic c hydrocarbons, e.g., chlorobenzene and dichlorobenzene), nitro compounds (such as nitromethane and nitroethane), nitriles (such as acetonitrile and benzonitrile), ethers (such as chain ethers, e.g., diethyl ether, diisopropyl ether, and dimethoxyethane; and cyclic ethers, e.g., tetrahydrofuran and dioxane), ketones (such as acetone, methyl ethyl ketone, and diisobutyl ketone), esters (such as ethyl acetate and butyl acetate), carbonates (such as dimethyl carbonate, diethyl carbonate, ethylene carbonate, and propylene carbonate), alcohols (such as methanol, ethanol, propanol, isopropyl alcohol, and butanol), carboxylic acids (such as acetic acid), and mixed solvents including any of these solvents and used. Of these, a solvent including at least a hydrocarbon (in particular, an aliphatic hydrocarbon such as hexane) is preferable as the precipitation or reprecipitation solvent. In such a solvent including at least a hydrocarbon, the ratio of the hydrocarbon (for example, an aliphatic hydrocarbon such as hexane) to other solvents (for example, esters such as ethyl acetate, and alcohols such as methanol and ethanol) is, for example, the former/the latter (volume ratio; 25° C.)=about 10/90 to 99/1, preferably the former/the latter (volume ratio; 25° C.)=about 30/70 to 98/2, more preferably the former/the latter (volume ratio; 25° C.)=about 50/50 to 97/3.

The amount of the precipitation or reprecipitation solvent used can be appropriately selected in consideration of, for example, the efficiency and the yield, and is generally 100 to 10,000 parts by mass, preferably 200 to 2,000 parts by mass, more preferably 300 to 1,000 parts by mass relative to 100 parts by mass of the polymer solution.

The diameter of a nozzle for feeding the polymer solution into the precipitation or reprecipitation solvent (poor solvent) is preferably 4 mm φ or less (for example, 0.2 to 4 mm q). The feeding rate (dropping rate) of the polymer solution into the poor solvent is, for example, about 0.1 to 10 m/see, preferably about 0.3 to 5 m/see in terms of linear speed.

The precipitation or reprecipitation operation is preferably performed with stirring. A mixing impeller used for stirring may be, for example, a disc turbine, a fan turbine (including a paddle), a curved blade turbine, an arrow blade turbine, a Pfaudler-type impeller, a Brumargin-type impeller, an angled blade fan turbine, a propeller, a multistage-type impeller, an anchor-type impeller (or a horseshoe-type impeller), a gate-type impeller, a double ribbon, or a screw. The stirring is preferably further performed for 10 minutes or more, particularly preferably 20 minutes or more, after completion of the feeding of the polymer solution. It is also possible to mix and stir the polymer solution and the poor solvent using a line mixer instead of the mixing impeller.

The temperature during precipitation or reprecipitation can be appropriately selected in consideration of the efficiency and operability, and is usually about 0° C. to 50° C., preferably around room temperature (for example, about 20° C. to 35° C.). The precipitation or reprecipitation operation can be performed by a publicly known method such as a batch method or a continuous method using a commonly used mixing vessel such as a stirring tank.

The precipitated or reprecipitated particulate polymer is usually subjected to commonly employed solid-liquid separation such as filtration or centrifugation, and dried for use. The filtration is performed using a solvent-resistant filter medium, preferably under pressure. The drying is performed under normal pressure or reduced pressure (preferably under reduced pressure) at a temperature of about 30° C. to 100° C., preferably about 30° C. to 50° C.

Incidentally, after the resin is once precipitated and separated, the resin may be dissolved in a solvent again and brought into contact with a solvent in which the resin is sparingly soluble or insoluble.

That is, the method may include, after completion of the radical polymerization reaction, contacting a solvent in which the resin is sparingly soluble or insoluble to precipitate the resin (step a), separating the resin from the solution (step b), dissolving the resin again in another solvent to prepare a resin solution A (step c), subsequently bringing the resin solution A into contact with a solvent in which the resin is sparingly soluble or insoluble in an amount less than 5 times the volume (preferably, 3 times or less the volume) of the resin solution A to precipitate a resin solid (step d), and separating the precipitated resin (step e).

The solvent used in the preparation of the resin solution A may be a solvent similar to the solvent for dissolving the monomer in the polymerization reaction, and may be the same as or different from the solvent used in the polymerization reaction.

The weight-average molecular weight (Mw_{B}) of the resin (B) is preferably 5,000 to 100,000, more preferably 10,000 to 90,000, still more preferably 12,000 to 85,000. Setting Mw_{B} within the above range to obtain an appropriate molecular weight is preferred because the solubility of the resin (B) can be appropriately adjusted. Note that Mw_{B} is a polystyrene-equivalent value measured by the GPC method described above.

In a chromatogram obtained by GPC of the resin (B), the area of a component having a weight-average molecular weight (Mw_{B}) of 10,000 or less is preferably 20% or less with respect to the total area excluding the peak areas of an unreacted polymerizable monomer and a polymerization solvent.

### The Chromatogram is Measured by the GPC Method Described Above.

The method for controlling the area of a component having a weight-average molecular weight (Mw_{B}) of 10,000 or less to 20% or less with respect to the total area excluding the peak areas of an unreacted polymerizable monomer and a polymerization solvent is not particularly limited, and an example thereof may include appropriately selecting a purification step after the synthesis of the resin (B).

The area of a component having a weight-average molecular weight (Mw_{B}) of 10,000 or less is preferably 20% or less, more preferably 15% or less with respect to the total area excluding the peak areas of an unreacted polymerizable monomer and a polymerization solvent.

In a preferred embodiment, in the chromatogram obtained by GPC of the resin (B), the area of a component having a weight-average molecular weight (Mw_{B}) of 10,000 or less is preferably 20% or less with respect to the total area excluding the peak areas of an unreacted polymerizable monomer and a polymerization solvent, and the resin (B) preferably has a Mw_{B} of 90,000 or less.

Preferably, the resin (B) does not substantially include a fluorine atom or a silicon atom. It is possible to prevent the resin (B) from being more hydrophobic and to prevent the resin (B) from being localized in a surface of the film to be obtained.

Preferably, the resin (B) does not substantially include a fluorine atom. Specifically, the content of a repeating unit having a fluorine atom or a silicon atom is preferably 5 mol % or less, more preferably 3 mol % or less, still more preferably 1 mol % or less, ideally 0 mol % relative to all the repeating units in the resin (B), that is, the resin (B) contains neither a fluorine atom nor a silicon atom.

The content (S_{B}) of the resin (B) relative to the total solid content in the composition according to the present invention is, on a mass basis, preferably 5 to 45 mass %, more preferably 5 to 35 mass %, still more preferably 5 to 30 mass %.

Such resins (B) may be used alone or in combination of two or more thereof. When two or more resins (B) are used in combination, the total amount thereof is preferably within the range described above.

The content of the resin (B) in the composition according to the present invention is preferably 50 parts by mass or less, more preferably 40 parts by mass or less relative to 100 parts by mass of the resin (A). Adjusting the content of the resin (B) in the composition is preferred because the resin (B) can be more moderately and homogeneously dispersed.

Compound (C) that Generates Acid Upon Irradiation with Actinic Ray or Radiation (Photoacid Generator)

The composition according to the present invention preferably contains a compound that generates an acid upon irradiation with an actinic ray or a radiation (also referred to as a “photoacid generator (C)”).

The photoacid generator (C) is not particularly limited as long as it is a compound that generates an acid upon irradiation with an actinic ray or a radiation.

The photoacid generator (C) may have the form of a low-molecular-weight compound or the form of being incorporated into a portion of a polymer. Alternatively, the form of a low-molecular-weight compound and the form of being incorporated into a portion of a polymer may be used in combination.

When the photoacid generator (C) has the form of a low-molecular-weight compound, the weight-average molecular weight (Mw) of the photoacid generator (C) is preferably 3,000 or less, more preferably 2,000 or less, still more preferably 1,000 or less.

The photoacid generator (C) may be incorporated into a portion of the resin (A) or the resin (B), or may be incorporated into a resin different from the resin (A) or the resin (B).

The photoacid generator (C) preferably has the form of a low-molecular-weight compound.

The photoacid generator (C) is preferably an ionic compound including a cation and an anion.

The photoacid generator (C) is preferably a compound that generates an organic acid upon irradiation with an actinic ray or a radiation, more preferably a compound that generates an organic acid upon irradiation with an actinic ray or a radiation and that has a fluorine atom or an iodine atom in the molecule. Examples of the organic acid include sulfonic acids (such as aliphatic sulfonic acids, aromatic sulfonic acids, and camphor sulfonic acid), carboxylic acids (such as aliphatic carboxylic acids, aromatic carboxylic acids, and aralkyl carboxylic acids), carbonylsulfonylimidic acid, bis(alkylsulfonyl) imidic acids, and tris(alkylsulfonyl) methide acids.

Examples of suitable forms of the photoacid generator (C) include a compound represented by General formula (ZI) below, a compound represented by General formula (ZII) below, and a compound represented by General formula (ZIII) below.

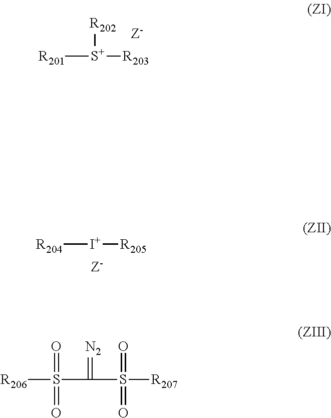

In General formula (ZI) above,

R₂₀₁, R₂₀₂, and R₂₀₃ each independently represent an organic group.

The number of carbon atoms of each of the organic groups serving as R₂₀₁, R₂₀₂, and R₂₀₃ is preferably 1 to 30, more preferably 1 to 20.

Two of R₂₀₁ to R₂₀₃ may be bonded together to form a ring structure, and the ring may include an oxygen atom, a sulfur atom, an ester bond, an amide bond, or a carbonyl group. Examples of the group formed by bonding two of R₂₀₁ to R₂₀₃ together include alkylene groups (such as a butylene group and a pentylene group) and —CH₂—CH₂—O—CH₂—CH₂—.

Z⁻ represents an anion.

### Cation in Compound Represented by General Formula (ZI)

Suitable forms of the cation in General formula (ZI) include corresponding groups in compounds (ZI-1), (ZI-2), (ZI-3), and (ZI-4) which will be described later.

The photoacid generator (C) may be a compound having a plurality of structures represented by General formula (ZI). For example, the photoacid generator (C) may be a compound having a structure in which at least one of R₂₀₁ to R₂₀₃ of a compound represented by General formula (ZI) and at least one of R₂₀₁ to R₂₀₃ of another compound represented by General formula (ZI) are bonded to each other through a single bond or a linking group.

### Compound (ZI-1)

First, the compound (ZI-1) will be described.

The compound (ZI-1) is an arylsulfonium compound in which at least one of R₂₀₁ to R₂₀₃ in General formula (ZI) above is an aryl group, that is, a compound having an arylsulfonium as a cation.

In the arylsulfonium compound, all of R₂₀₁ to R₂₀₃ may be aryl groups, or some of R₂₀₁ to R₂₀₃ may be aryl groups and the remainder may be an alkyl group or a cycloalkyl group.

Examples of the arylsulfonium compound include triarylsulfonium compounds, diarylalkylsulfonium compounds, aryldialkylsulfonium compounds, diarylcycloalkylsulfonium compounds, and aryldicycloalkylsulfonium compounds.

The aryl group of the arylsulfonium compound is preferably a phenyl group or a naphthyl group, more preferably a phenyl group. The aryl group may be an aryl group having a heterocyclic structure having, for example, an oxygen atom, a nitrogen atom, or a sulfur atom. Examples of the heterocyclic structure include a pyrrole residue, a furan residue, a thiophene residue, an indole residue, a benzofuran residue, and a benzothiophene residue. When the arylsulfonium compound has two or more aryl groups, the two or more aryl groups may be the same or different.

The alkyl group or the cycloalkyl group that the arylsulfonium compound optionally has is preferably a linear alkyl group having 1 to 15 carbon atoms, a branched alkyl group having 3 to 15 carbon atoms, or a cycloalkyl group having 3 to 15 carbon atoms, and examples thereof include a methyl group, an ethyl group, a propyl group, a n-butyl group, a sec-butyl group, a t-butyl group, a cyclopropyl group, a cyclobutyl group, and a cyclohexyl group.

The aryl group, the alkyl group, and the cycloalkyl group in R₂₀₁ to R₂₀₃ may each independently have, as a substituent, an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a halogen atom, a hydroxyl group, or a phenylthio group.

### Compound (ZI-2)

Next, the compound (ZI-2) will be described.

The compound (ZI-2) is a compound in which R₂₀₁ to R₂₀₃ in General formula (ZI) each independently represent an organic group having no aromatic ring. Herein, the aromatic ring also encompasses aromatic rings containing a heteroatom.

In R₂₀₁ to R₂₀₃, the organic group having no aromatic ring generally has 1 to 30 carbon atoms, preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, still more preferably a linear or branched 2-oxoalkyl group.

In R₂₀₁ to R₂₀₃, the alkyl group and the cycloalkyl group are preferably a linear alkyl group having 1 to 10 carbon atoms or a branched alkyl group having 3 to 10 carbon atoms (for example, a methyl group, an ethyl group, a propyl group, a butyl group, or a pentyl group), and a cycloalkyl group having 3 to 10 carbon atoms (for example, a cyclopentyl group, a cyclohexyl group, or a norbornyl group).

R₂₀₁ to R₂₀₃ may be further substituted with a halogen atom, an alkoxy group (having, for example, 1 to 5 carbon atoms), a hydroxyl group, a cyano group, or a nitro group.

### Compound (ZI-3)

Next, the compound (ZI-3) will be described.

The compound (ZI-3) is a compound represented by General formula (ZI-3) below and having a phenacylsulfonium salt structure.

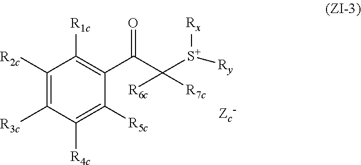

In General formula (ZI-3),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Zc⁻ represents an anion.

Any two or more of R_{1c} to R_{5c}, R_{5c} and R_{6c}, R_{6c} and R_{7c}, R_{5c} and Rₓ, and Rₓ and R_{y} may be individually bonded together to form ring structures, and these ring structures may each independently include an oxygen atom, a sulfur atom, a ketone group, an ester bond, or an amide bond.

Examples of the ring structure include aromatic or non-aromatic hydrocarbon rings, aromatic or non-aromatic heterocycles, and polycyclic fused rings formed by a combination of two or more of these rings. The ring structure may be a three to ten-membered ring, and is preferably a four to eight-membered ring, more preferably a five- or six-membered ring.

Examples of the groups formed by bonding together any two or more of R_{1c} to R_{5c}, R_{6c} and R_{7c}, and Rₓ and R_{y} include a butylene group and a pentylene group.

The groups formed by bonding together R_{5c} and R_{6c}, and R_{5c} and Rₓ are each preferably a single bond or an alkylene group. Examples of the alkylene group include a methylene group and an ethylene group.

The alkyl group serving as R_{6c} and R_{7c} is not particularly limited, but may be linear or branched, and is preferably an alkyl group having 1 to 20 carbon atoms, more preferably an alkyl group having 1 to 15 carbon atoms, still more preferably an alkyl group having 1 to 10 carbon atoms.

The alkyl group may have a substituent.

The cycloalkyl group serving as R_{6c} and R_{7c} is not particularly limited, but may be monocyclic or polycyclic cyclic, and is preferably a cycloalkyl group having 3 to 20 carbon atoms, more preferably a cycloalkyl group having 3 to 15 carbon atoms, still more preferably a cycloalkyl group having 3 to 10 carbon atoms.

The cycloalkyl group may be specifically a cyclopentyl group, a cyclohexyl group, or a decahydronaphthalenyl group.

The cycloalkyl group may have a substituent.

The aryl group serving as R_{6c} and R_{7c} is not particularly limited, but may be monocyclic or polycyclic, and is preferably an aryl group having 6 to 20 carbon atoms, more preferably an aryl group having 6 to 15 carbon atoms, still more preferably an aryl group having 6 to 10 carbon atoms.

The aryl group may have a substituent.

R_{6c} and R_{7c} are each independently preferably a hydrogen atom, an alkyl group, or a cycloalkyl group, more preferably a hydrogen atom or an alkyl group.

The alkyl group serving as Rₓ and R_{y} is not particularly limited, but may be linear or branched, and is preferably an alkyl group having 1 to 20 carbon atoms, more preferably an alkyl group having 1 to 15 carbon atoms, still more preferably an alkyl group having 1 to 10 carbon atoms.

The alkyl group may have a substituent.

The cycloalkyl group serving as Rₓ and R_{y} is not particularly limited, but may be monocyclic or polycyclic cyclic, and is preferably a cycloalkyl group having 3 to 20 carbon atoms, more preferably a cycloalkyl group having 3 to 15 carbon atoms, still more preferably a cycloalkyl group having 3 to 10 carbon atoms.

The cycloalkyl group may be specifically a cyclopentyl group, a cyclohexyl group, or a decahydronaphthalenyl group.

The cycloalkyl group may have a substituent.

The 2-oxoalkyl group serving as Rₓ and R_{y} is not particularly limited, but is preferably a 2-oxoalkyl group having 1 to 20 carbon atoms, more preferably a 2-oxoalkyl group having 1 to 15 carbon atoms, still more preferably a 2-oxoalkyl group having 1 to 10 carbon atoms.

The 2-oxoalkyl group may have a substituent.

The 2-oxocycloalkyl group serving as Rₓ and R_{y} is not particularly limited, but is preferably a 2-oxocycloalkyl group having 3 to 20 carbon atoms, more preferably a 2-oxocycloalkyl group having 3 to 15 carbon atoms, still more preferably a 2-oxocycloalkyl group having 3 to 10 carbon atoms.

The 2-oxocycloalkyl group may have a substituent.

The alkoxycarbonylalkyl group serving as Rₓ and R_{y} is not particularly limited, but is preferably an alkoxycarbonylalkyl group having 3 to 22 carbon atoms, more preferably an alkoxycarbonylalkyl group having 3 to 17 carbon atoms, still more preferably an alkoxycarbonylalkyl group having 3 to 12 carbon atoms.

The alkoxycarbonylalkyl group may have a substituent.

Rₓ and R_{y} may be linked together to form a ring, and this ring structure may include an oxygen atom, a nitrogen atom, a sulfur atom, a ketone group, an ether bond, an ester bond, or an amide bond.

The ring structure preferably includes an oxygen atom.

Examples of the ring structure include aromatic or non-aromatic hydrocarbon rings, aromatic or non-aromatic heterocycles, and polycyclic fused rings formed by a combination of two or more of these rings. The ring structure may be a three to ten-membered ring, and is preferably a four to eight-membered ring, more preferably a five- or six-membered ring.

### Compound (ZI-4)

Next, the compound (ZI-4) will be described.

The compound (ZI-4) is represented by General formula (ZI-4) below.

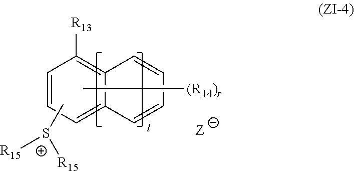

In General formula (ZI-4),

1 represents an integer of 0 to 2.

r represents an integer of 0 to 8.

R₁₃ represents a hydrogen atom, a fluorine atom, a hydroxyl group, an alkyl group, a cycloalkyl group, an alkoxy group, or an alkoxycarbonyl group.

R₁₄ represents a hydroxyl group, an alkyl group, a cycloalkyl group, an alkoxy group, an alkoxycarbonyl group, an alkylcarbonyl group, an alkylsulfonyl group, or a cycloalkylsulfonyl group. When a plurality of R₁₄'s are present, they may be the same or different.

R₁₅'s each independently represent an alkyl group, a cycloalkyl group, or a naphthyl group. Two R₁₅'s may be bonded together to form a ring. When two R₁₅'s are bonded together to form a ring, the ring skeleton may include a heteroatom such as an oxygen atom or a nitrogen atom.

Z⁻ represents an anion.

In General formula (ZI-4), each of the alkyl groups in R₁₃, R₁₄ and R₁₅ is linear or branched and is preferably an alkyl group having 1 to 10 carbon atoms, more preferably, for example, a methyl group, an ethyl group, a n-butyl group, or a t-butyl group.

The alkyl group serving as R₁₃ is not particularly limited, may be linear or branched, and is preferably an alkyl group having 1 to 20 carbon atoms, more preferably an alkyl group having 1 to 15 carbon atoms, still more preferably an alkyl group having 1 to 10 carbon atoms. Specifically, a methyl group, an ethyl group, a n-butyl group, or a t-butyl group is preferred.

The alkyl group may have a substituent.

The cycloalkyl group serving as R₁₃ is not particularly limited, may be monocyclic or polycyclic, and is preferably a cycloalkyl group having 3 to 20 carbon atoms, more preferably a cycloalkyl group having 3 to 15 carbon atoms, still more preferably a cycloalkyl group having 3 to 10 carbon atoms.

The cycloalkyl group may be specifically a cyclopentyl group, a cyclohexyl group, or a decahydronaphthalenyl group.

The cycloalkyl group may have a substituent.

The alkoxy group serving as R₁₃ is not particularly limited, but is preferably an alkoxy group having 1 to 20 carbon atoms, more preferably an alkoxy group having 1 to 15 carbon atoms, still more preferably an alkoxy group having 1 to 10 carbon atoms.

The alkoxy group may have a substituent.

The alkoxycarbonyl group serving as R₁₃ is not particularly limited, but is preferably an alkoxycarbonyl group having 2 to 21 carbon atoms, more preferably an alkoxycarbonyl group having 2 to 16 carbon atoms, still more preferably an alkoxycarbonyl group having 2 to 11 carbon atoms.

The alkoxycarbonyl group may have a substituent.

The alkyl group serving as R₁₄ is not particularly limited, may be linear or branched, and is preferably an alkyl group having 1 to 20 carbon atoms, more preferably an alkyl group having 1 to 15 carbon atoms, still more preferably an alkyl group having 1 to 10 carbon atoms. Specifically, a methyl group, an ethyl group, a n-butyl group, or a t-butyl group is preferred.

The alkyl group may have a substituent.

The cycloalkyl group serving as R₁₄ is not particularly limited, may be monocyclic or polycyclic, and is preferably a cycloalkyl group having 3 to 20 carbon atoms, more preferably a cycloalkyl group having 3 to 15 carbon atoms, still more preferably a cycloalkyl group having 3 to 10 carbon atoms.

The cycloalkyl group may be specifically a cyclopentyl group, a cyclohexyl group, or a decahydronaphthalenyl group.

The cycloalkyl group may have a substituent.

The alkoxy group serving as R₁₄ is not particularly limited, but is preferably an alkoxy group having 1 to 20 carbon atoms, more preferably an alkoxy group having 1 to 15 carbon atoms, still more preferably an alkoxy group having 1 to 10 carbon atoms.

The alkoxy group may have a substituent.

The alkoxycarbonyl group serving as R₁₄ is not particularly limited, but is preferably an alkoxycarbonyl group having 2 to 21 carbon atoms, more preferably an alkoxycarbonyl group having 2 to 16 carbon atoms, still more preferably an alkoxycarbonyl group having 2 to 11 carbon atoms.

The alkoxycarbonyl group may have a substituent.

The alkylcarbonyl group serving as R₁₄ is not particularly limited, but is preferably an alkylcarbonyl group having 2 to 21 carbon atoms, more preferably an alkylcarbonyl group having 2 to 16 carbon atoms, still more preferably an alkylcarbonyl group having 2 to 11 carbon atoms.

The alkylcarbonyl group may have a substituent.

The alkylsulfonyl group serving as R₁₄ is not particularly limited, but is preferably an alkylsulfonyl group having 1 to 20 carbon atoms, more preferably an alkylsulfonyl group having 1 to 15 carbon atoms, still more preferably an alkylsulfonyl group having 1 to 10 carbon atoms.

The alkylsulfonyl group may have a substituent.

The cycloalkylsulfonyl group serving as R₁₄ is not particularly limited, but is preferably a cycloalkylsulfonyl group having 3 to 20 carbon atoms, more preferably a cycloalkylsulfonyl group having 3 to 15 carbon atoms, still more preferably a cycloalkylsulfonyl group having 3 to 10 carbon atoms.

The cycloalkylsulfonyl group may have a substituent.

When a plurality of R₁₄'s are present, the plurality of R₁₄'s may be the same or different from each other.

The alkyl group serving as each R₁₅ is not particularly limited, may be linear or branched, and is preferably an alkyl group having 1 to 20 carbon atoms, more preferably an alkyl group having 1 to 15 carbon atoms, still more preferably an alkyl group having 1 to 10 carbon atoms. Specifically, a methyl group, an ethyl group, a n-butyl group, or a t-butyl group is preferred.

The alkyl group may have a substituent.

The cycloalkyl group serving as each R₁₅ is not particularly limited, may be monocyclic or polycyclic, and is preferably a cycloalkyl group having 3 to 20 carbon atoms, more preferably a cycloalkyl group having 3 to 15 carbon atoms, still more preferably a cycloalkyl group having 3 to 10 carbon atoms.

The cycloalkyl group may be specifically a cyclopentyl group, a cyclohexyl group, or a decahydronaphthalenyl group.

The cycloalkyl group may have a substituent.

The naphthyl group serving as R₁₅ may have a substituent.

Two R₁₅'s may be bonded together to form a ring. When two R₁₅'s are bonded together to form a ring, this ring structure may include an oxygen atom, a nitrogen atom, a sulfur atom, a ketone group, an ether bond, an ester bond, or an amide bond.

The ring structure preferably includes an oxygen atom.

Examples of the ring structure include aromatic or non-aromatic hydrocarbon rings, aromatic or non-aromatic heterocycles, and polycyclic fused rings formed by a combination of two or more of these rings. The ring structure may be a three to ten-membered ring, and is preferably a four to eight-membered ring, more preferably a five- or six-membered ring.

In a preferred embodiment, two R₁₅'s are preferably alkyl groups and are preferably bonded together to form a ring structure.

### Cation in Compound Represented by General Formula (ZII) or General Formula (ZIII)

Next, General formulae (ZII) and (ZIII) will be described.

In General formulae (ZII) and (ZIII), R₂₀₄ to R₂₀₇ each independently represent an aryl group, an alkyl group, or a cycloalkyl group.

In R₂₀₄ to R₂₀₇, the aryl group is preferably a phenyl group or a naphthyl group, more preferably a phenyl group. In R₂₀₄ to R₂₀₇, the aryl group may be an aryl group having a heterocyclic structure having, for example, an oxygen atom, a nitrogen atom, or a sulfur atom. Examples of the skeleton of the aryl group having a heterocyclic structure include pyrrole, furan, thiophene, indole, benzofuran, and benzothiophene.

In R₂₀₄ to R₂₀₇, the alkyl group and the cycloalkyl group are preferably a linear alkyl group having 1 to 10 carbon atoms or a branched alkyl group having 3 to 10 carbon atoms (for example, a methyl group, an ethyl group, a propyl group, a butyl group, or a pentyl group), and a cycloalkyl group having 3 to 10 carbon atoms (for example, a cyclopentyl group, a cyclohexyl group, or a norbornyl group).

In R₂₀₄ to R₂₀₇, the aryl group, the alkyl group, and the cycloalkyl group may each independently have a substituent. Examples of the substituent that the aryl group, the alkyl group, and the cycloalkyl group in R₂₀₄ to R₂₀₇ may have include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxyl group, and a phenylthio group.

Z⁻ represents an anion.

### Anion in Compound Represented by General Formula (ZI), General Formula (ZII), General Formula (ZI-3), or General Formula (ZI-4)

Z⁻ in General formula (ZI), Z⁻ in General formula (ZII), Zc⁻ in General formula (ZI-3), and Z⁻ in General formula (ZI-4) are each preferably an anion represented by General formula (3) below.

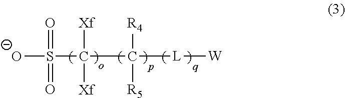

In General formula (3),

Xf's each independently represent a fluorine atom or an alkyl group substituted with at least one fluorine atom.

R₄ and R₅ each independently represent a hydrogen atom, a fluorine atom, an alkyl group, or an alkyl group substituted with at least one fluorine atom, and when a plurality of R₄'s and R₅'s are present, they may be the same or different.

L represents a divalent linking group, and when a plurality of L's are present, they may be the same or different.

W represents an organic group.

o represents an integer of 1 to 3. p represents an integer of 0 to 10. q represents an integer of 0 to 10.

Xf's each represent a fluorine atom or an alkyl group substituted with at least one fluorine atom. The number of carbon atoms of the alkyl group is preferably 1 to 10, more preferably 1 to 4. The alkyl group substituted with at least one fluorine atom is preferably a perfluoroalkyl group. The plurality of Xf's present may be the same or different.

Xf is preferably a fluorine atom or a perfluoroalkyl group having 1 to 4 carbon atoms. Xf is more preferably a fluorine atom or CF3. In particular, all Xf's are each a fluorine atom.

R₄ and R₅ each independently represent a hydrogen atom, a fluorine atom, an alkyl group, or an alkyl group substituted with at least one fluorine atom. When a plurality of R₄'s and R₅'s are present, they may be the same or different.

The alkyl groups serving as R₄ and R₅ may have substituents and preferably have 1 to 4 carbon atoms. R₄ and R₅ are preferably hydrogen atoms.

Specific examples and suitable forms of the alkyl group substituted with at least one fluorine atom are the same as specific examples and suitable forms of Xf in General formula (3).

L represents a divalent linking group, and when a plurality of L's are present, they may be the same or different.

Examples of the divalent linking group include —COO—(—C(═O)—O—), —OCO—, —CONH—, —NHCO—, —CO—, —O—, —S—, —SO—, —SO₂—, alkylene groups (preferably having 1 to 6 carbon atoms), cycloalkylene groups (preferably having 3 to 15 carbon atoms), alkenylene groups (preferably having 2 to 6 carbon atoms), and divalent linking groups provided by combining a plurality of the foregoing. Of these, —COO—, —OCO—, —CONH—, —NHCO—, —CO—, —O—, —SO₂—, —COO-alkylene group-, —OCO-alkylene group-, —CONH-alkylene group-, or —NHCO-alkylene group— is preferred, and —COO—, —OCO—, —CONH—, —SO₂—, —COO-alkylene group-, or —OCO-alkylene group— is more preferred.

W represents an organic group.

The number of carbon atoms of the organic group is not particularly limited, but is generally 1 to 30, preferably 1 to 20.

The organic group is not particularly limited, but represents, for example, an alkyl group or an alkoxy group.

The alkyl group is not particularly limited, may be linear or branched, and is preferably an alkyl group having 1 to 10 carbon atoms, more preferably an alkyl group having 1 to 6 carbon atoms, still more preferably an alkyl group having 1 to 4 carbon atoms.

The alkyl group and the alkoxy group may have a substituent. The substituent is not particularly limited, may be, for example, substituent T described above, and is preferably a fluorine atom.

W preferably represents an organic group including a ring structure. Among these, a cyclic organic group is preferred.

The cyclic organic group may be, for example, an alicyclic group, an aryl group, or a heterocyclic group.

The alicyclic group may be monocyclic or polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Of these, an alicyclic group having a bulky structure with 7 or more carbon atoms, such as a norbornyl group, a tricyclodecanyl group, a tetracyclodecanyl group, a tetracyclododecanyl group, or an adamantyl group, is preferred.

The aryl group may be monocyclic or polycyclic. Examples of the aryl group include a phenyl group, a naphthyl group, a phenanthryl group, and an anthryl group.

The heterocyclic group may be monocyclic or polycyclic. A polycyclic heterocyclic group can further suppress the diffusion of an acid. The heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle having no aromaticity include a tetrahydropyran ring, a lactone ring, a sultone ring, and a decahydroisoquinoline ring. Examples of the lactone ring and the sultone ring include the lactone structures and sultone structures exemplified in the resin described above. The heterocycle in the heterocyclic group is particularly preferably a furan ring, a thiophene ring, a pyridine ring, or a decahydroisoquinoline ring.

The cyclic organic group may have a substituent. The substituent may be, for example, an alkyl group (that may be linear or branched and preferably have 1 to 12 carbon atoms), a cycloalkyl group (that may be monocyclic, polycyclic, or spirocyclic and preferably have 3 to 20 carbon atoms), an aryl group (preferably having 6 to 14 carbon atoms), a hydroxyl group, an alkoxy group, an ester group, an amide group, a urethane group, a ureido group, a thioether group, a sulfonamide group, or a sulfonic acid ester group. The carbon constituting the cyclic organic group (carbon that contributes to ring formation) may be carbonyl carbon.

Z⁻ in General formula (ZI), Z⁻ in General formula (ZII), Zc⁻ in General formula (ZI-3), and Z⁻ in General formula (ZI-4) are also each preferably an anion represented by General formula (An-2) or (An-3) below.

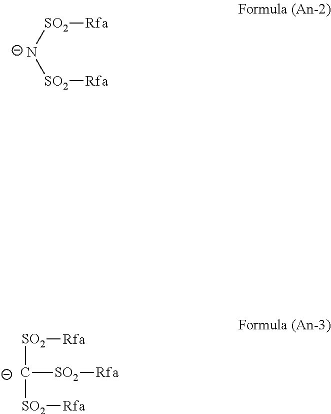

In General formulae (An-2) and (An-3), Rfa's each independently represent a monovalent organic group having a fluorine atom, and the plurality of Rfa's may be bonded together to form a ring.

Rfa is preferably an alkyl group substituted with at least one fluorine atom. The number of carbon atoms of the alkyl group is preferably 1 to 10, more preferably 1 to 4. The alkyl group substituted with at least one fluorine atom is preferably a perfluoroalkyl group.

Preferred examples of a sulfonium cation in General formula (ZI) and an iodonium cation in General formula (ZII) are shown below.

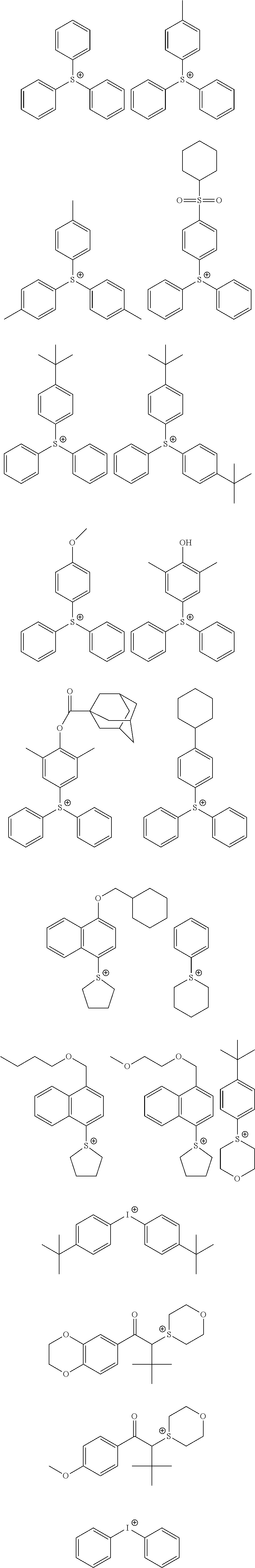

Preferred examples of the anion Z⁻ in General formula (ZI) and General formula (ZII), Zc⁻ in General formula (ZI-3), and Z⁻ in General formula (ZI-4) are shown below.

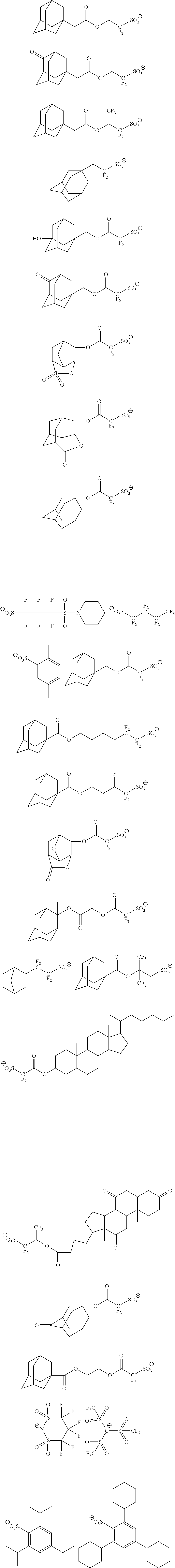

The content of the photoacid generator (C) in the composition according to the present invention is, on a mass basis, preferably 0.1 to 20 mass %, more preferably 0.5 to 15 mass %, still more preferably 0.5 to 10 mass % relative to the total solid content of the composition.

Such photoacid generators (C) may be used alone or in combination of two or more thereof. When two or more photoacid generators (C) are used in combination, the total amount thereof is preferably within the range described above.

### Acid Diffusion Control Agent (D)

The composition according to the present invention preferably contains an acid diffusion control agent (also referred to as an “acid diffusion control agent (D)).

The acid diffusion control agent (D) serves as a quencher that traps an acid generated from the photoacid generator (C) or the like upon exposure and that suppresses a reaction of the resin (A) and the resin (B) (acid decomposable resin) in an unexposed region due to an excess of the generated acid.

Examples of the acid diffusion control agent (D) that can be used include a basic compound (DA), a basic compound (DB) that undergoes a decrease or loss of the basicity upon irradiation with an actinic ray or a radiation, an onium salt (DC) serving as a weak acid relative to the photoacid generator (C), a low-molecular-weight compound (DD) having a nitrogen atom and having a group that leaves due to the action of an acid, and an onium salt compound (DE) having a nitrogen atom in a cationic moiety.

As the acid diffusion control agent (D), publicly known acid diffusion control agents can be appropriately used. For example, the publicly known compounds disclosed in paragraphs [0627] to [0664] of US2016/0070167A, paragraphs [0095] to [0187] of US2015/0004544A, paragraphs [0403] to [0423] of US2016/0237190A, and paragraphs [0295] to [0328] of US2016/0274458A can be suitably used as the acid diffusion control agent (D).

Examples of the basic compound (DA) include compounds described in paragraphs 0188 to 0208 of JP2019-045864A.

In the present invention, an onium salt (DC) serving as a weak acid relative to the photoacid generator (C) may also be used as the acid diffusion control agent (D).

In the case of using a photoacid generator (C) and an onium salt that generates an acid weaker than the acid generated from the photoacid generator (C) as a mixture, when the acid generated from the photoacid generator (C) upon irradiation with an actinic ray or a radiation collides with the onium salt having an unreacted weak-acid anion, the weak acid is released by salt exchange to generate an onium salt having a strong-acid anion. It is considered that, in this process, since the strong acid is exchanged with the weak acid having a lower catalytic ability, the acid is apparently deactivated and acid diffusion can be controlled.

Examples of the onium salt that generates an acid weaker than the acid generated from the photoacid generator (C) include the onium salts described in paragraphs 0224 to 0233 of JP2019-070676A.

Preferred examples of the basic compound (DA) include compounds having structures represented by Formulae (A) to (E) below.

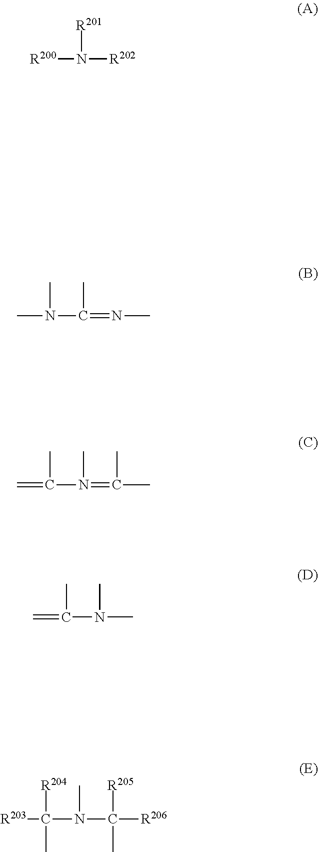

In General formulae (A) and (E),

R²⁰⁰, R²⁰¹, and R²⁰² may be the same or different and each independently represent a hydrogen atom, an alkyl group (preferably having 1 to 20 carbon atoms), a cycloalkyl group (preferably having 3 to 20 carbon atoms), an aryl group (preferably having 6 to 20 carbon atoms), an alkylcarbonyl group (preferably having 2 to 21 carbon atoms), a cycloalkylcarbonyl group (preferably having 4 to 21 carbon atoms), an arylcarbonyl group (preferably having 7 to 21 carbon atoms), an alkylsulfonyl group (preferably having 1 to 20 carbon atoms), a cycloalkylsulfonyl group (preferably having 3 to 20 carbon atoms), or an arylsulfonyl group (preferably having 6 to 20 carbon atoms). At least two of R²⁰⁰, R²⁰¹, and R²⁰² may be bonded together to form a ring, and the ring may include at least one of an oxygen atom, a sulfur atom, an ester bond, an amide bond, a carbonyl group, or a sulfonyl group.

R²⁰³, R²⁰⁴, R²⁰⁵, and R²⁰⁶ may be the same or different, and each independently represent an alkyl group having 1 to 20 carbon atoms.

With regard to the alkyl groups, an alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in General formulae (A) and (E) are more preferably unsubstituted.

The basic compound (DA) is preferably, for example, guanidine, aminopyrrolidine, pyrazole, pyrazoline, piperazine, aminomorpholine, aminoalkylmorpholine, or piperidine, more preferably, for example, a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, or an aniline derivative having a hydroxyl group and/or an ether bond.

The basic compound (DB) that undergoes a decrease or loss of the basicity upon irradiation with an actinic ray or a radiation (hereinafter, also referred to as a “compound (DB)”) is a compound that has a proton acceptor functional group and is decomposed upon irradiation with an actinic ray or a radiation to undergo a decrease or loss of the proton acceptor property or a change from the proton acceptor property to the acidity.

The proton acceptor functional group is a group that electrostatically interacts with a proton or a functional group having an electron, and means, for example, a functional group having a macrocyclic structure such as cyclic polyether, or a functional group having a nitrogen atom having an unshared electron pair that does not contribute to π-conjugation. Examples of the nitrogen atom having an unshared electron pair that does not contribute to π-conjugation include nitrogen atoms having moieties represented by formulae below.

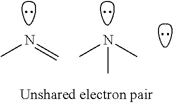

Preferred examples of the moiety of the proton acceptor functional group include crown ether, azacrown ether, primary to tertiary amine, pyridine, imidazole, and pyrazine structures.

The compound (DB) is decomposed by irradiation with an actinic ray or a radiation to generate a compound that has undergone a decrease or loss of the proton acceptor property or a change from the proton acceptor property to the acidity. Herein, the phrase “a decrease or loss of the proton acceptor property or a change from the proton acceptor property to the acidity” refers to a change in the proton acceptor property caused by the addition of a proton to the proton acceptor functional group, and specifically means that, when a proton adduct is generated from the compound (DB) having a proton acceptor functional group and a proton, the equilibrium constant in the chemical equilibrium decreases.

The proton acceptor property can be confirmed by pH measurement.

The acid dissociation constant pKa of the compound generated as a result of decomposition of the compound (DB) upon irradiation with an actinic ray or a radiation preferably satisfies pKa<−1, more preferably satisfies −13<pKa<−1, and still more preferably satisfies −13<pKa<−3.

The acid-dissociation constant pKa represents an acid-dissociation constant pKa in an aqueous solution and is defined in, for example, Kagaku Binran (Handbook of Chemistry) (II) (revised 4th edition, 1993, edited by The Chemical Society of Japan, Maruzen Publishing Co., Ltd.). A lower value of the acid dissociation constant pKa indicates a higher acid strength. Specifically, the acid dissociation constant pKa in an aqueous solution can be actually measured by measuring an acid dissociation constant at 25° C. using an infinitely dilute aqueous solution. Alternatively, a value based on the Hammett's substituent constant and the database of values in publicly known documents can be determined by calculation using the following Software package 1. All the values of pKa described in the present specification are values determined by calculation using this software package.

### Software Package 1: Advanced Chemistry Development (ACD/Labs) Software V8.14 for Solaris (1994-2007 ACD/Labs)

In the composition according to the present invention, the onium salt (DC) serving as a weak acid relative to the acid generator can be used as the acid diffusion control agent.

In the case of using an acid generator and an onium salt that generates an acid weaker than the acid generated from the acid generator as a mixture, when the acid generated from the acid generator upon irradiation with an actinic ray or a radiation collides with the onium salt having an unreacted weak-acid anion, the weak acid is released by salt exchange to generate an onium salt having a strong acid anion. In this process, since the strong acid is exchanged with the weak acid having a lower catalytic ability, the acid is apparently deactivated and acid diffusion can be controlled.

The onium salts serving as weak acids relative to the acid generator are preferably compounds represented by General formulae (d1-1) to (d1-3) below.

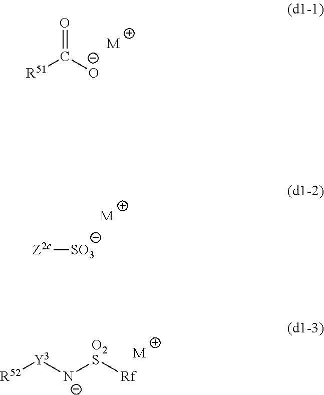

In the formulae, R⁵¹ is a hydrocarbon group that may have a substituent, Z^{2c} is a hydrocarbon group that may have a substituent and has 1 to 30 carbon atoms (provided that the carbon atom adjacent to S is not substituted with fluorine atoms), R⁵² is an organic group, Y³ is a linear, branched, or cyclic alkylene group or an arylene group, Rf is a hydrocarbon group including a fluorine atom, and M+'s are each independently an ammonium cation, a sulfonium cation, or an iodonium cation.

Preferred examples of the sulfonium cation or the iodonium cation represented by M⁺ include the sulfonium cations exemplified in General formula (ZI) and the iodonium cations exemplified in General formula (ZII).

The onium salt (DC) serving as a weak acid relative to the acid generator may be a compound (hereinafter, also referred to as a “compound (DCA)”) which has a cationic moiety and an anionic moiety in the same molecule and in which the cationic moiety and the anionic moiety are linked together via a covalent bond.

The compound (DCA) is preferably a compound represented by any one of General Formulae (C-1) to (C-3) below.

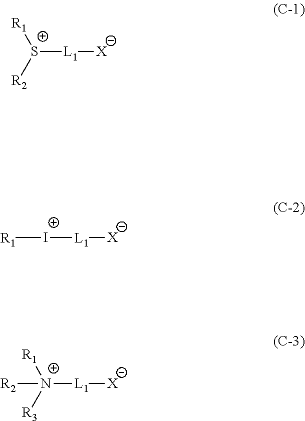

In General formulae (C-1) to (C-3),

R₁, R₂, and R₃ each independently represent a substituent having 1 or more carbon atoms.

L₁ represents a divalent linking group or a single bond that links together a cationic moiety and an anionic moiety.

—X⁻ represents an anionic moiety selected from the group consisting of —COO, —SO₃, —SO₂⁻, and —N⁻—R₄. R₄ represents a monovalent substituent having at least one of a carbonyl group (—C(═O)—), a sulfonyl group (—S(═O)₂—), or a sulfinyl group (—S(═O)—) at the linking site to the adjacent N atom.

R₁, R₂, R₃, R₄, and L₁ may be bonded together to form a ring structure. In General formula (C-3), two of R₁ to R₃ may be combined to represent a single divalent substituent, and may be bonded to the N atom via a double bond.

Examples of the substituent having 1 or more carbon atoms in R₁ to R₃ include alkyl groups, cycloalkyl groups, aryl groups, alkyloxycarbonyl groups, cycloalkyloxycarbonyl groups, aryloxycarbonyl groups, alkylaminocarbonyl groups, cycloalkylaminocarbonyl groups, and arylaminocarbonyl groups. An alkyl group, a cycloalkyl group, or an aryl group is preferred.

Examples of L₁ serving as a divalent linking group include linear or branched alkylene groups, cycloalkylene groups, arylene groups, a carbonyl group, an ether bond, an ester bond, an amide bond, a urethane bond, a urea bond, and groups provided by combining two or more of the foregoing. L₁ is preferably an alkylene group, an arylene group, an ether bond, an ester bond, or a group provided by combining two or more of the foregoing.

The low-molecular-weight compound (DD) having a nitrogen atom and having a group that leaves due to the action of an acid (hereinafter, also referred to as a “compound (DD)”) is preferably an amine derivative having, on the nitrogen atom, a group that leaves due to the action of an acid.

The group that leaves due to the action of an acid is preferably an acetal group, a carbonate group, a carbamate group, a tertiary ester group, a tertiary hydroxyl group, or a hemiaminal ether group, more preferably a carbamate group or a hemiaminal ether group.

The molecular weight of the compound (DD) is preferably 100 to 1,000, more preferably 100 to 700, still more preferably 100 to 500.

The compound (DD) may have a carbamate group having a protective group on the nitrogen atom. The protective group constituting the carbamate group can be represented by General formula (d-1) below.

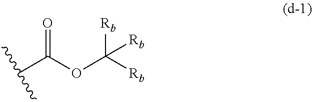

In General formula (d-1),

Rb's each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). Rb's may be linked together to form a ring.

The alkyl groups, the cycloalkyl groups, the aryl groups, and the aralkyl groups represented by Rb's may each independently be substituted with a functional group such as a hydroxyl group, a cyano group, an amino group, a pyrrolidino group, a piperidino group, a morpholino group, or an oxo group, an alkoxy group, or a halogen atom. The same applies to the alkoxyalkyl groups represented by Rb's.

Rb is preferably a linear or branched alkyl group, a cycloalkyl group, or an aryl group, more preferably a linear or branched alkyl group or a cycloalkyl group.

Examples of the ring formed by linking two Rb's together include alicyclic hydrocarbons, aromatic hydrocarbons, heterocyclic hydrocarbons, and derivatives thereof.

Specific examples of the structure of the group represented by General formula (d-1) include, but are not limited to, the structures disclosed in paragraph of US2012/0135348A1.

The compound (DD) preferably has a structure represented by General formula (6) below.

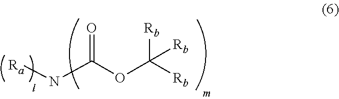

In General formula (6),

1 represents an integer of 0 to 2, m represents an integer of 1 to 3, and 1+m=3 is satisfied.

Ra represents a hydrogen atom, an alkyl group, a cycloalkyl group, an aryl group, or an aralkyl group. When l is 2, two Ra's may be the same or different, and two Ra's may be linked together to form a heterocycle together with the nitrogen atom in the formula. The heterocycle may include a heteroatom other than the nitrogen atom in the formula.

Rb's have the same definition as Rb's in General formula (d-1) above, and preferred examples thereof are also the same.

In General formula (6), the alkyl group, the cycloalkyl group, the aryl group, and the aralkyl group serving as Ra may each independently be substituted with the same groups as the groups described above as the groups with which the alkyl group, the cycloalkyl group, the aryl group, and the aralkyl group serving as Rb's may be substituted.

In Ra above, specific examples of the alkyl group, the cycloalkyl group, the aryl group, and the aralkyl group (these groups may be substituted with the above-described groups) include the same groups as the specific examples described above for Rb.

Particularly preferred, specific examples of the structure of the compound (DD) in the present invention include, but are not limited to, the compounds disclosed in paragraph of US2012/0135348A1.

The onium salt compound (DE) having a nitrogen atom in the cationic moiety (hereinafter, also referred to as a “compound (DE)”) is preferably a compound having a basic moiety including a nitrogen atom in the cationic moiety. The basic moiety is preferably an amino group, more preferably an aliphatic amino group. Still more preferably, all of the atoms adjacent to the nitrogen atom in the basic moiety are hydrogen atoms or carbon atoms. From the viewpoint of improving the basicity, preferably, an electron withdrawing functional group (such as a carbonyl group, a sulfonyl group, a cyano group, or a halogen atom) is not directly bonded to the nitrogen atom.

Specific examples of preferred structure of the compound (DE) include, but are not limited to, the compounds disclosed in paragraph of US2015/0309408A1.

In the composition according to the present invention, the content of the acid diffusion control agent (D) (in the case where a plurality of acid diffusion control agents are present, the total content thereof) relative to the total solid content of the composition according to the present invention is preferably 0.01 to 10.0 mass %, more preferably 0.01 to 5.0 mass %.

In the present invention, such acid diffusion control agents (D) may be used alone or in combination of two or more thereof.

### Solvent

The composition according to the present invention preferably contains a solvent (also referred to as a “solvent(S)”).

The solvent(S) preferably includes at least one of (M1) a propylene glycol monoalkyl ether carboxylate or (M2) at least one selected from the group consisting of propylene glycol monoalkyl ethers, lactates, acetates, alkoxypropionates, chain ketones, cyclic ketones, lactones, and alkylene carbonates. In this case, the solvent may further include a component other than the components (M1) and (M2).

Use of the solvent including the component (M1) or (M2) in combination with the resin (A) and the resin (B) is preferred because coatability of the actinic ray-sensitive or radiation-sensitive resin composition is improved, and a pattern having few development defects can be formed.

Examples of the solvent(S) include organic solvents such as alkylene glycol monoalkyl ether carboxylates, alkylene glycol monoalkyl ethers, alkyl lactates, alkyl alkoxypropionates, cyclic lactones (preferably having 4 to 10 carbon atoms), monoketone compounds (preferably having 4 to 10 carbon atoms) that may include a ring, alkylene carbonates, alkyl alkoxyacetates, and alkyl pyruvates.

The content of the solvent(S) in the composition according to the present invention is preferably adjusted so that the concentration of solid contents of the composition according to the present invention is 15 to 45 mass %, and more preferably adjusted so that the concentration of solid contents of the composition according to the present invention is 20 to 45 mass %. Note that the concentration of solid contents means the mass percentage of the mass of components other than the solvent (components that can constitute an actinic ray-sensitive or radiation-sensitive film) relative to the total mass of the actinic ray-sensitive or radiation-sensitive resin composition.

### Surfactant

The composition according to the present invention may include a surfactant (also referred to as a “surfactant (E)). When the composition according to the present invention includes a surfactant, a pattern having higher adhesiveness and fewer development defects can be formed.

The surfactant (E) is preferably a fluorine-based and/or silicone-based surfactant.

Examples of the fluorine-based and/or silicone-based surfactants include the surfactants described in paragraph 0276 of US2008/0248425A. Furthermore, EFTOP EF301 or EF303 (manufactured by Shin-Akita Kasei Co., Ltd.); FLUORAD FC430, 431, or 4430 (manufactured by Sumitomo 3M Limited); MEGAFACE F171, F173, F176, F189, F113, F110, F177, F120, or R08 (manufacturer by DIC Corporation); Surflon S-382, SC101, 102, 103, 104, 105, or 106 (manufacturer by AGC Inc.); Troysol S-366 (manufactured by Troy Chemical Industries, Inc.); GF-300 or GF-150 (manufactured by TOAGOSEI Co., Ltd.); SURFLON S-393 (manufactured by SEIMI CHEMICAL Co., Ltd.); EFTOP EF121, EF122A, EF122B, RF122C, EF125M, EF135M, EF351, EF352, EF801, EF802, or EF601 (manufactured by JEMCO); PF636, PF656, PF6320, or PF6520 (manufactured by OMNOVA Solutions Inc.); KH-20 (manufactured by Asahi Kasei Corporation); or FTX-204G, 208G, 218G, 230G, 204D, 208D, 212D, 218D, or 222D (manufactured by NEOS COMPANY LIMITED) may be used. A polysiloxane polymer KP-341 (manufactured by Shin-Etsu Chemical Co., Ltd.) can also be used as the silicon-based surfactant.

In addition to the publicly known surfactants as described above, the surfactant (E) may be synthesized using a fluoroaliphatic compound produced by a telomerization method (also referred to as a telomer method) or an oligomerization method (also referred to as an oligomer method). Specifically, a polymer including a fluoroaliphatic group derived from the fluoroaliphatic compound may be used as the surfactant. The fluoroaliphatic compound can be synthesized by, for example, the method described in JP2002-90991A.

The polymer having a fluoroaliphatic group is preferably a copolymer of a monomer having a fluoroaliphatic group and a (poly(oxyalkylene)) acrylate and/or a (poly(oxyalkylene)) methacrylate, which may be randomly distributed or block-copolymerized. Examples of the poly(oxyalkylene) group include a poly(oxyethylene) group, a poly(oxypropylene) group, and a poly(oxybutylene) group. The poly(oxyalkylene) group may be a unit having alkylenes with different chain lengths in the same chain, such as poly(oxyethylene/oxypropylene/oxyethylene block linkage) or poly(oxyethylene/oxypropylene block linkage). Furthermore, the copolymer of a monomer having a fluoroaliphatic group and a (poly(oxyalkylene)) acrylate (or methacrylate) is not limited to a binary copolymer, but may be a ternary or higher copolymer obtained by simultaneous copolymerization of, for example, two or more different monomers having a fluoroaliphatic group and two or more different (poly(oxyalkylene)) acrylates (or methacrylates).

Examples of commercially available surfactants include MEGAFACE F178, F-470, F-473, F-475, F-476, and F-472 (manufactured by DIC Corporation), copolymers of an acrylate (or methacrylate) having a C₆F₁₃ group and a (poly(oxyalkylene)) acrylate (or methacrylate), and copolymers of an acrylate (or methacrylate) having a C₃F₇ group, (poly(oxyethylene)) acrylate (or methacrylate), and (poly(oxypropylene)) acrylate (or methacrylate).

Surfactants other than fluorine-based and/or silicon-based surfactants, described in paragraph of US2008/0248425A may be used.

Such surfactants (E) may be used alone or in combination of two or more thereof.

The composition according to the present invention may or may not contain the surfactant (E). When the composition according to the present invention contains the surfactant (E), the content of the surfactant (E) is preferably 0.0001 to 2 mass %, more preferably 0.0005 to 1 mass % relative to the total solid content of the composition according to the present invention.

### Hydrophobic Resin

The composition according to the present invention may include a hydrophobic resin (also referred to as a “hydrophobic resin (F)”).

The hydrophobic resin (F) is a resin that is hydrophobic and different from the resin (A) and the resin (B) described above.

The hydrophobic resin (F) is preferably designed so as to be localized in the surface of the resist film; however, unlike surfactants, the hydrophobic resin (F) is not necessarily required to have a hydrophilic group in the molecule and does not necessarily contribute to homogeneous mixing of a polar substance and a nonpolar substance.

Advantages due to the addition of the hydrophobic resin (F) are, for example, the control of static and dynamic contact angles at the surface of the resist film for water, and the suppression of outgassing.

The hydrophobic resin (F) preferably has any one or more, more preferably two or more, selected from the group consisting of “a fluorine atom”, “a silicon atom”, and “a CH₃ moiety included in a side chain moiety of the resin” from the viewpoint of localization in the surface layer of the film. The hydrophobic resin (F) preferably has a hydrocarbon group having 5 or more carbon atoms. The resin may have such a group in the main chain thereof or, as a substituent, in a side chain thereof.

When the hydrophobic resin (F) includes a fluorine atom and/or a silicon atom, the fluorine atom and/or the silicon atom in the hydrophobic resin may be included in the main chain of the resin or may be included in a side chain.

When the hydrophobic resin (F) has a fluorine atom, a moiety having a fluorine atom is preferably an alkyl group having a fluorine atom, a cycloalkyl group having a fluorine atom, or an aryl group having a fluorine atom.

The alkyl group having a fluorine atom (preferably having 1 to 10 carbon atoms and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom may be an aryl group, such as a phenyl group or a naphthyl group, in which at least one hydrogen atom is substituted with a fluorine atom, and may further have a substituent other than a fluorine atom.

Examples of a repeating unit having a fluorine atom or a silicon atom include those exemplified in paragraph 0519 of US2012/0251948A.

As described above, it is also preferable that the hydrophobic resin (F) have a CH₃ moiety in a side chain moiety.

Herein, the CH₃ moiety that a side chain moiety in the hydrophobic resin has includes CH₃ moieties having an ethyl group, a propyl group, or the like.

On the other hand, a methyl group directly bonded to the main chain of the hydrophobic resin (F) (for example, an α-methyl group of a repeating unit having a methacrylic acid structure) has a small contribution to the surface localization of the hydrophobic resin (F) because of the influence of the main chain, and therefore, is not included in the CH₃ moiety in the present invention.

Regarding the hydrophobic resin (F), the description in paragraphs 0348 to 0415 of JP2014-010245A can be referred to, and the contents thereof are incorporated herein by reference.

As the hydrophobic resin (F), the resins described in JP2011-248019A, JP2010-175859A, and JP2012-032544A also can be preferably used.

The composition according to the present invention may or may not contain the hydrophobic resin (F). When the composition according to the present invention contains the hydrophobic resin (F), the content of the hydrophobic resin (F) is preferably 0.01 to 20 mass %, more preferably 0.1 to 15 mass % relative to the total solid content of the composition according to the present invention.

### Other Components

The composition according to the present invention may contain components other than the components described above. Examples of the other components include crosslinking agents, alkali-soluble resins, dissolution inhibiting compounds, dyes, plasticizers, photosensitizers, light absorbents, and compounds that improve solubility in developers.

The concentration of solid contents of the composition according to the present invention is 15 mass % or more. With such a value, the composition can be suitably used as a resist composition for a thick film.

From the viewpoint of providing better effects of the present invention, the concentration of solid contents of the composition according to the present invention is preferably 20 mass % or more, particularly preferably 20 to 45 mass %. Note that the concentration of solid contents means the mass percentage of the mass of components other than the solvent (components that can constitute an actinic ray-sensitive or radiation-sensitive film) relative to the total mass of the actinic ray-sensitive or radiation-sensitive resin composition.

The content of a compound having an ethylenically unsaturated bond and included in the composition according to the present invention is preferably 1.0 mass % or less in the total solid content.

A content of the compound of 1.0 mass % or less in the total solid content is preferred because impurities in the composition according to the present invention can be reduced, and therefore, defects in a pattern after the lapse of time can be further reduced.

The method for controlling the content of the compound to 1.0 mass % or less in the total solid content is not particularly limited, and a publicly known purification method can be used.

The content of the compound having an ethylenically unsaturated bond and included in the composition according to the present invention is the value calculated, as a ratio of a component having a molecular weight of 1,000 or less in a resin, using a value obtained by [(A)/((A)+(B))]×100(%) where (A) is the area of a pattern detected on the low-molecular-weight side and (B) is the area detected on the high-molecular-weight side, as measured with a differential refractive index detector (RI) of GPC using monodisperse PHS (polystyrene) having a molecular weight (MW) of 1,000 as a standard sample (standard).

### Viscosity

The viscosity of the composition according to the present invention is not particularly limited, but is preferably 200 to 500 mPa·s, more preferably 250 to 450 mPa·s, still more preferably 300 to 400 mPa·s at 25° C. The viscosity of the actinic ray-sensitive or radiation-sensitive resin composition is determined by conducting measurement at 25° C. using an E-type viscometer (Model RE-85L, manufactured by Toki Sangyo Co., Ltd.).

### Preparation Method

The composition according to the present invention can be prepared by dissolving the resin (A), the resin (B), the photoacid generator (C), and the optional above-described components in a solvent (preferably the solvent described above), and filtering the resulting solution through a filter.

The pore size of the filter used for filter filtration is not particularly limited, but is preferably 3 μm or less, more preferably 0.5 μm or less, still more preferably 0.3 μm or less. In some cases, it is also preferable that the pore size of the filter be 0.1 μm or less, 0.05 μm or less, and 0.03 μm or less. The filter is preferably formed of polytetrafluoroethylene, polyethylene, or nylon. In filter filtration, for example, as disclosed in JP2002-62667A, circulation filtration may be performed, or filtration may be performed by connecting a plurality of types of filters in series or in parallel. The composition may be filtered multiple times. Furthermore, the composition may be subjected to, for example, deaeration treatment before or after the filter filtration.

### Applications

The composition according to the present invention reacts upon irradiation with an actinic ray or radiation to undergo a change in a property. The composition according to the present invention can be used for a step of producing a semiconductor such as an integrated circuit (IC), production of a circuit board for, for example, liquid crystal or a thermal head, production of an imprint mold structure, other photofabrication steps, or production of a planographic plate or an acid-curable composition, for example. A pattern formed using the composition according to the present invention can be used in an etching step, an ion implanting step, a bump electrode formation step, a redistribution formation step, and micro electro mechanical systems (MEMS), for example.

### Pattern Forming Method and Actinic Ray-Sensitive or Radiation-Sensitive Film

A pattern forming method according to the present invention has
a step of forming, on a substrate, an actinic ray-sensitive or radiation-sensitive film (preferably a resist film) using the above-described actinic ray-sensitive or radiation-sensitive resin composition according to the present invention;
a step of exposing the actinic ray-sensitive or radiation-sensitive film to obtain an exposed actinic ray-sensitive or radiation-sensitive film; and
a step of, using a developer, developing the exposed actinic ray-sensitive or radiation-sensitive film to form a pattern.

Hereinafter, each of the steps will be described in detail.

### Step a: Actinic Ray-Sensitive or Radiation-Sensitive Film Formation Step

A step a is a step of forming, on a substrate, an actinic ray-sensitive or radiation-sensitive film using the composition according to the present invention.

An example of the method for forming, on a substrate, an actinic ray-sensitive or radiation-sensitive film using the composition according to the present invention may be a method of applying the composition according to the present invention onto a substrate.

The composition according to the present invention can be applied onto a substrate (for example, formed of silicon and covered with silicon dioxide) as used in the production of an integrated circuit element by a suitable coating method using a spinner, a coater, or the like. The coating method is preferably spin-coating using a spinner.

After the application of the composition according to the present invention, the substrate may be dried to form an actinic ray-sensitive or radiation-sensitive film. Note that, if necessary, various underlying films (an inorganic film, an organic film, or an antireflection film) may be formed as underlayers of the actinic ray-sensitive or radiation-sensitive film.

The drying method is, for example, a method of heating (prebaking: PB). The heating can be performed using means included in an ordinary exposure device and/or an ordinary development device, or may be performed using a hot plate, for example.

The heating temperature is preferably 80° C. to 150° C., more preferably 80° C. to 140° C.

The heating time is preferably 30 to 1,000 seconds, more preferably 40 to 800 seconds.

The film thickness of the actinic ray-sensitive or radiation-sensitive film is not particularly limited.

When the actinic ray-sensitive or radiation-sensitive film is an actinic ray-sensitive or radiation-sensitive film for KrF exposure, the film thickness is preferably 5 μm or more, more preferably 5 μm or more and 30 μm or less, still more preferably 7 μm or more and 15 μm or less.

When the actinic ray-sensitive or radiation-sensitive film is a resist film for ArF exposure or EUV exposure, the film thickness is preferably 10 to 700 nm, more preferably 20 to 400 nm.

The present invention also relates to an actinic ray-sensitive or radiation-sensitive film formed using the composition according to the present invention. When the film thickness of the actinic ray-sensitive or radiation-sensitive film is 500 nm or more, an advantageous effect of the present invention that development defects after the lapse of time can be reduced is remarkably exhibited.

As an overlying layer of the actinic ray-sensitive or radiation-sensitive film, a topcoat may be formed using a topcoat composition.

Preferably, the topcoat composition does not mix with the actinic ray-sensitive or radiation-sensitive film and further can be uniformly applied as an overlying layer of the actinic ray-sensitive or radiation-sensitive film.

The film thickness of the topcoat is preferably 10 to 200 nm, more preferably 20 to 100 nm.

The topcoat is not particularly limited, and a publicly known topcoat can be formed by a publicly known method. For example, a topcoat can be formed on the basis of the description of paragraphs 0072 to 0082 of JP2014-059543A.

### Step b: Exposure Step

A step b is a step of exposing the actinic ray-sensitive or radiation-sensitive film to obtain an exposed actinic ray-sensitive or radiation-sensitive film.

An example of the exposure method may be a method of applying an actinic ray or radiation either through a mask disposed between a light source and an actinic ray-sensitive or radiation-sensitive film or without disposing a mask directly.

Examples of the actinic ray or radiation include infrared light, visible light, ultraviolet light, far-ultraviolet light, extreme ultraviolet light, X-rays, and electron beams (EB). For example, KrF excimer laser (248 nm), ArF excimer laser (193 nm), F₂ excimer laser (157 nm), EUV (13 nm), X-rays, and EB are preferred.

The light source for exposure in the step b is particularly preferably KrF.

After the exposure and before development, baking (post-exposure baking: PEB) is preferably performed.

The heating temperature is preferably 80° C. to 150° C., more preferably 80° C. to 140° C.

The heating time is preferably 10 to 1,000 seconds, more preferably 10 to 180 seconds.

The heating can be performed using means included in an ordinary exposure device and/or an ordinary development device, or may be performed using a hot plate, for example.

This step is also referred to as post-exposure baking.

### Step c: Development Step

A step c is a step of, using a developer, developing the exposed actinic ray-sensitive or radiation-sensitive film to form a pattern.

Examples of the development method include a method of immersing, for a predetermined time, the substrate in a tank filled with the developer (dipping method), a method of puddling the developer on the surface of the substrate using surface tension and leaving the developer at rest for a predetermined time to perform development (puddling method), a method of spraying the developer onto the surface of the substrate (spraying method), and a method of continuously ejecting the developer over the substrate rotating at a constant rate, while scanning a developer ejection nozzle at a constant rate, (dynamic dispensing method).

After the step of performing development, a step of stopping the development while performing replacement with another solvent may be performed.

The development time is not particularly limited as long as the resin in the unexposed regions is sufficiently dissolved within the time, and is preferably 10 to 300 seconds, more preferably 20 to 120 seconds.

The temperature of the developer is preferably 0° C. to 50° C., more preferably 15° C. to 35° C.

Examples of the developer include alkali developers and organic solvent developers.

As the alkali developer, an alkali aqueous solution including an alkali is preferably used. In particular, the alkali developer is preferably an aqueous solution of a quaternary ammonium salt represented by tetramethylammonium hydroxide (TMAH). An appropriate amount of an alcohol, a surfactant, or the like may be added to the alkali developer. The alkali developer usually has an alkali concentration of 0.1 to 20 mass %. The alkali developer usually has a pH of 10.0 to 15.0.

The organic solvent developer is a developer including an organic solvent.

Examples of the organic solvent used in the organic solvent developer include publicly known organic solvents, such as ester-based solvents, ketone-based solvents, alcohol-based solvents, amide-based solvents, ether-based solvents, and hydrocarbon-based solvents.

### Other Steps

The pattern forming method according to the present invention may include, after the step c, a step of performing washing with a rinsing liquid.

After the development step using an alkali developer, the rinsing liquid used in the rinsing step may be, for example, pure water. An appropriate amount of surfactant may be added to the rinsing liquid.

After the development step using an organic-based developer, the rinsing liquid used in the rinsing step is not particularly limited as long as the rinsing liquid does not dissolve the resist pattern, and may be a solution including a common organic solvent. A rinsing liquid containing at least one organic solvent selected from the group consisting of hydrocarbon-based solvents, ketone-based solvents, ester-based solvents, alcohol-based solvents, amide-based solvents, and ether-based solvents is preferably used as the rinsing liquid. An appropriate amount of surfactant may be added to the rinsing liquid.

The formed pattern may be used as a mask to perform etching treatment of the substrate. Specifically, the pattern formed in the step c may be used as a mask to process the substrate (or the underlayer film and the substrate), thereby forming a pattern in the substrate.

The method of processing the substrate (or the underlayer film and the substrate) is not particularly limited, but is preferably a method of subjecting the substrate (or the underlayer film and the substrate) to dry etching using the pattern formed in the step c as a mask, thereby forming a pattern in the substrate.

The dry etching may be a single-step etching or a multi-step etching. When the etching is performed in multiple steps, the etching treatment in each step may be the same or different.

For the etching, any publicly known method may be used, and various conditions and the like are appropriately determined depending on, for example, the type or use of the substrate. For example, the etching can be carried out in accordance with, for example, Proceedings of International Society for Optics and Photonics (Proc. of SPIE), Vol. 6924, 692420 (2008) and JP2009-267112A. The etching may also be carried out in accordance with the method described in “Chapter 4, Etching” of “Semiconductor Process Textbook”, 4th edition, issued in 2007, publisher: SEMI Japan”.

The dry etching is preferably oxygen plasma etching.

Various materials used in the present invention (for example, the solvent, the developer, the rinsing liquid, the antireflection film-forming composition, and the topcoat-forming composition) preferably do not include impurities such as metal. The content of impurities included in such materials is preferably 1 mass ppm (parts per million) or less, more preferably 10 mass ppb (parts per billion) or less, still more preferably 100 mass ppt (parts per trillion) or less, particularly preferably 10 mass ppt or less, most preferably 1 mass ppt or less. Examples of metal impurities include Na, K, Ca, Fe, Cu, Mn, Mg, Al, Li, Cr, Ni, Sn, Ag, As, Au, Ba, Cd, Co, Mo, Zr, Pb, Ti, V, W, and Zn.

The method for removing impurities, such as metal, from the various materials may be, for example, filtration using a filter. The filter pore diameter is preferably 0.20 μm or less, more preferably 0.05 μm or less, still more preferably 0.01 μm or less.

As the material of the filter, fluororesins such as polytetrafluoroethylene (PTFE) and perfluoroalkoxy alkanes (PFA), polyolefin resins such as polypropylene and polyethylene, and polyamide resins such as nylon 6 and nylon 66 are preferred. The filter may be washed with an organic solvent in advance and used. In the filter filtration step, a plurality of filters or a plurality of types of filters may be connected in series or in parallel and used. When a plurality of types of filters are used, filters having different pore diameters and/or composed of different materials may be used in combination. The various materials may be filtered a plurality of times, and the step of performing filtration a plurality of times may be a circulation filtration step. The circulation filtration step is preferably, for example, a method disclosed in JP2002-62667A.

The filter is preferably a filter in which an eluted substance is reduced as disclosed in JP2016-201426A.

Instead of filter filtration, an adsorbing material may be used to remove impurities. Alternatively, filter filtration and an adsorbing material may be used in combination. Publicly known adsorbing materials can be used as such adsorbing materials, and, for example, an inorganic adsorbing material such as silica gel or zeolite, or an organic adsorbing material such as activated carbon can be used. Examples of metal adsorbents include those disclosed in JP2016-206500A.

Examples of the method of reducing the amount of impurities such as metal included in the various materials include a method of selecting, as raw materials constituting the various materials, raw materials having low metal contents, a method of subjecting raw materials constituting the various materials to filter filtration, and a method of performing distillation under conditions in which contamination is minimized by, for example, lining or coating the interior of the apparatus with a fluororesin or the like. Preferred conditions for the filter filtration performed for the raw materials constituting the various materials are the same as those described above.

The above various materials are preferably stored in containers described in, for example, US2015/0227049A, JP2015-123351A, or JP2017-13804A in order to prevent the entry of impurities.

The various materials may be diluted with a solvent used in the composition and then used.

The present invention also relates to a method for producing an electronic device, the method including the above-described pattern forming method.

The electronic device according to the present invention is suitably mounted on electric or electronic devices (such as household appliances, office automation (OA), media-related devices, optical devices, and communication devices).

### EXAMPLES

Hereinafter, the present invention will be described in more detail with reference to Examples. Materials, amounts used, ratios, details of treatment, orders of treatments, and the like described in the following Examples can be appropriately changed without departing from the spirit and scope of the present invention. The scope of the present invention is not construed as being limited to the following Examples.

### Resin (A)

Resins A-1 and A-2 below were used as the resin (A).

The number-average molecular weight (Mn), the weight-average molecular weight (Mw), and the dispersity (molecular weight distribution (Mw/Mn)) of each resin are polystyrene equivalent values determined, using a gel permeation chromatography (GPC) apparatus (HLC-8120GPC manufactured by Tosoh Corporation), by GPC measurement (solvent: tetrahydrofuran, amount of flow (amount of sample injected): 10 μL, column: TSK gel Multipore HXL-M manufactured by Tosoh Corporation, column temperature: 40° C., flow rate: 1.0 mL/min, detector: differential refractive index detector (Refractive Index Detector)).

The compositional ratio (unit:mol %) of repeating units in each resin was measured by ¹³C-NMR (nuclear magnetic resonance).

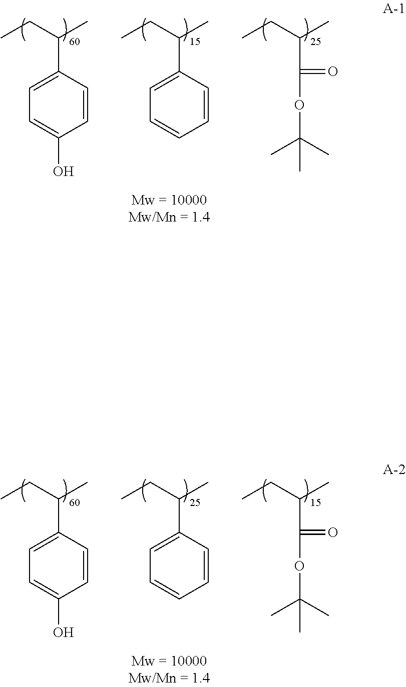

### Resin (B)

Resins B-1 to B-29 below were used as the resin (B).

The number-average molecular weight (Mn), the weight-average molecular weight (Mw), and the dispersity (molecular weight distribution (Mw/Mn)) of each resin are polystyrene equivalent values determined, using a gel permeation chromatography (GPC) apparatus (HLC-8120GPC manufactured by Tosoh Corporation), by GPC measurement (solvent: tetrahydrofuran, amount of flow (amount of sample injected): 10 μL, column: TSK gel Multipore HXL-M manufactured by Tosoh Corporation, column temperature: 40° C., flow rate: 1.0 mL/min, detector: differential refractive index detector (Refractive Index Detector)).

The compositional ratio (unit:mol %) of repeating units in each resin was measured by ¹³C-NMR (nuclear magnetic resonance).

Resins B-101 to B-103 do not correspond to the resin (B) but are described for convenience.

TABLE 1

| | Compositional ratio | | | | | | | | | | | | | | | | |
|---|---|---|---|---|---|---|---|---|---|---|---|---|---|---|---|---|---|
| | | | | | | | | | | | | | Repeating | | | | |
| | Repeating unit (1) | | | | | | | | | | Repeating unit (2) | | unit (3) | | | | |
| Resin (B) | 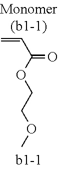 | 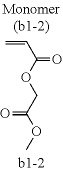 | 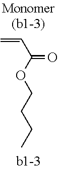 | 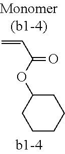 | 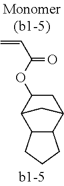 | 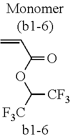 | 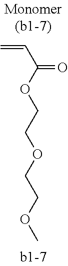 | 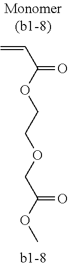 | 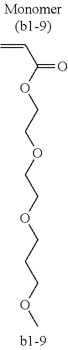 [SMILES: C=CC(=O)OCCOCCOCCCOC] | 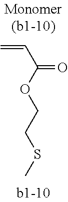 | 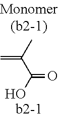 | 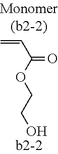 | 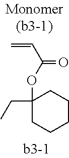 | Weight- average molecu- lar weight | Dis- persity | Area of 10000 or less | Content repeat- ing having fluorine atom |
| B-1 | 40 | 0 | 15 | 30 | 0 | 0 | 0 | 0 | 0 | 0 | 15 | 0 | 0 | 21700 | 1.7 | 3% | 0 |
| B-2 | 40 | 0 | 15 | 30 | 0 | 0 | 0 | 0 | 0 | 0 | 15 | 0 | 0 | 25000 | 2.9 | 13% | 0 |
| B-3 | 40 | 0 | 15 | 30 | 0 | 0 | 0 | 0 | 0 | 0 | 15 | 0 | 0 | 25800 | 2.1 | 5% | 0 |
| B-4 | 0 | 40 | 15 | 30 | 0 | 0 | 0 | 0 | 0 | 0 | 15 | 0 | 0 | 23800 | 1.7 | 4% | 0 |
| B-5 | 40 | 0 | 20 | 10 | 30 | 0 | 0 | 0 | 0 | 0 | 0 | 0 | 0 | 22600 | 1.7 | 3% | 0 |
| B-6 | 40 | 0 | 15 | 0 | 0 | 30 | 0 | 0 | 0 | 0 | 15 | 0 | 0 | 25700 | 1.7 | 1% | 30 |
| B-7 | 40 | 0 | 15 | 30 | 0 | 0 | 0 | 0 | 0 | 0 | 15 | 0 | 0 | 23000 | 1.7 | 1% | 0 |
| B-8 | 40 | 0 | 15 | 30 | 0 | 0 | 0 | 0 | 0 | 0 | 15 | 0 | 0 | 15400 | 1.7 | 8% | 0 |
| B-9 | 40 | 0 | 15 | 30 | 0 | 0 | 0 | 0 | 0 | 0 | 15 | 0 | 0 | 18100 | 1.7 | 3% | 0 |
| B-10 | 40 | 0 | 13 | 30 | 0 | 0 | 0 | 0 | 0 | 0 | 15 | 0 | 0 | 23000 | 1.7 | 4% | 0 |
| B-11 | 40 | 0 | 13 | 30 | 0 | 0 | 0 | 0 | 0 | 0 | 15 | 0 | 0 | 8700 | 1.7 | 28% | 0 |
| B-12 | 40 | 0 | 15 | 30 | 0 | 0 | 0 | 0 | 0 | 0 | 15 | 0 | 0 | 98600 | 1.7 | 0% | 0 |
| B-13 | 40 | 0 | 15 | 30 | 0 | 0 | 0 | 0 | 0 | 0 | 15 | 0 | 0 | 10300 | 1.7 | 16% | 0 |
| B-14 | 40 | 0 | 15 | 30 | 0 | 0 | 0 | 0 | 0 | 0 | 15 | 0 | 0 | 55000 | 1.7 | 0% | 0 |
| B-15 | 40 | 0 | 15 | 30 | 0 | 0 | 0 | 0 | 0 | 0 | 15 | 0 | 0 | 88000 | 1.7 | 0% | 0 |
| B-16 | 40 | 0 | 15 | 25 | 0 | 0 | 0 | 0 | 0 | 0 | 15 | 0 | 5 | 24800 | 1.7 | 2% | 0 |

TABLE 2

| | Compositional ratio. | | | | | | | | | | | | | | | | |
|---|---|---|---|---|---|---|---|---|---|---|---|---|---|---|---|---|---|
| | | | | | | | | | | | | | Repeating | | | | |
| | Repeating unit (1) | | | | | | | | | | Repeating unit (2) | | Ant (3) | | | | |
| Resin (B) | 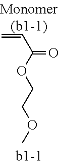 | 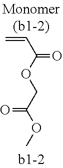 | 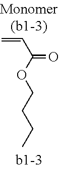 | 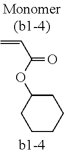 | 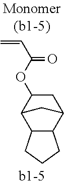 | 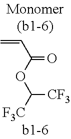 | 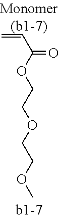 | 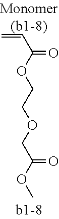 | 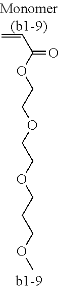 [SMILES: C=CC(=O)OCCOCCOCCCOC] | 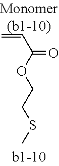 | 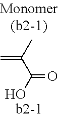 | 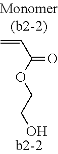 | 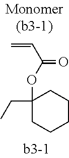 | Weight- average molecu- lar weight | Dis- persity | Area of 10000 or less | Content of repeat- ing unit having fluorine atom (mol %) |
| B-17 | 40 | 0 | 15 | 0 | 30 | 0 | 0 | 0 | 0 | 0 | 15 | 0 | 0 | 33000 | 1.7 | 3% | 0 |
| B-18 | 40 | 0 | 45 | 0 | 0 | 0 | 0 | 0 | 0 | 0 | 15 | 0 | 0 | 27800 | 1.7 | 0% | 0 |
| B-19 | 55 | 0 | 0 | 30 | 0 | 0 | 0 | 0 | 0 | 0 | 15 | 0 | 0 | 24200 | 1.7 | 2% | 0 |
| B-20 | 25 | 0 | 30 | 30 | 0 | 0 | 0 | 0 | 0 | 0 | 15 | 0 | 0 | 26700 | 1.7 | 0% | 0 |
| B-21 | 90 | 0 | 0 | 0 | 0 | 0 | 0 | 0 | 0 | 0 | 10 | 0 | 0 | 24900 | 1.7 | 1% | 0 |
| B-22 | 65 | 0 | 25 | 0 | 0 | 0 | 0 | 0 | 0 | 0 | 10 | 0 | 0 | 28400 | 1.7 | 2% | 0 |
| B-23 | 40 | 0 | 45 | 0 | 0 | 0 | 0 | 0 | 0 | 0 | 15 | 0 | 0 | 22200 | 1.7 | 1% | 0 |
| B-24 | 40 | 0 | 45 | 0 | 0 | 0 | 0 | 0 | 0 | 0 | 15 | 0 | 0 | 24000 | 1.7 | 1% | 0 |
| B-25 | 0 | 0 | 15 | 30 | 0 | 0 | 40 | 0 | 0 | 0 | 15 | 0 | 0 | 29600 | 1.7 | 1% | 0 |
| B-26 | 0 | 0 | 15 | 30 | 0 | 0 | 0 | 40 | 0 | 0 | 15 | 0 | 0 | 18700 | 1.7 | 6% | 0 |
| B-27 | 0 | 0 | 15 | 30 | 0 | 0 | 0 | 0 | 40 | 0 | 15 | 0 | 0 | 23000 | 1.7 | 1% | 0 |
| B-28 | 0 | 0 | 15 | 30 | 0 | 0 | 0 | 0 | 0 | 40 | 15 | 0 | 0 | 23000 | 1.7 | 1% | 0 |
| B-29 | 40 | 0 | 15 | 30 | 0 | 0 | 0 | 0 | 0 | 0 | 0 | 15 | 0 | 20000 | 1.7 | 3% | 0 |
| B-101 | 40 | 0 | 15 | 0 | 30 | 0 | 0 | 0 | 0 | 0 | 15 | 0 | 0 | 24300 | 3.2 | 19% | 0 |
| B-102 | 0 | 0 | 40 | 10 | 30 | 0 | 0 | 0 | 0 | 0 | 20 | 0 | 0 | 23300 | 1.7 | 3% | 0 |
| B-103 | 40 | 0 | 15 | 0 | 20 | 0 | 0 | 0 | 0 | 0 | 15 | 0 | 10 | 24300 | 1.7 | 1% | 0 |

In Table 1, regarding repeating units (1) to (3), monomers corresponding to the repeating units (1) to (3) are shown.

In the repeating unit (1), the repeating unit corresponding to the monomer (b1-1), the repeating unit corresponding to the monomer (b1-2), the repeating unit corresponding to the monomer (b1-7), and the repeating unit corresponding to the monomer (b1-10) each correspond to the repeating unit (b1).

In the repeating unit (2), the repeating unit corresponding to the monomer (b2-2) corresponds to the repeating unit (b1) and also corresponds to the repeating unit (b2).

In the chromatogram obtained by GPC of each of the resins B-1 to B-29 and the resins B-101 to B-103, the area (%) of a component having a weight-average molecular weight (Mw_{B}) of 10,000 or less with respect to the total area excluding the peak areas of an unreacted polymerizable monomer and a polymerization solvent is described in the column of “Area of 10000 or less”. The measurement method is as described above.

The content (mol %) of a repeating unit including a fluorine atom relative to all the repeating units in the resin (B) is described in the column of “Content of repeating unit having fluorine atom”.

### Synthesis Example 1: Synthesis of Resin B-1

### Radical Polymerization

Under a stream of nitrogen, 8.6 g of cyclohexanone was placed in a three-necked flask, and the flask was heated to 80° C. A solution prepared by dissolving, in 79 g of cyclohexanone, 8.0 g of 2-methoxyethyl acrylate, 2.9 g of normal-butyl acrylate, 7.1 g of cyclohexyl acrylate, 2.0 g of methacrylic acid, and a polymerization initiator V-601 (manufactured by FUJIFILM Wako Pure Chemical Corporation) in an amount of 8 mol % relative to the monomers was added dropwise thereto over six hours. After completion of the dropwise addition, the reaction mixture was further reacted at 80° C. for two hours. The reaction mixture was allowed to cool and then added dropwise to a liquid mixture of hexane 800 mL/ethyl acetate 200 mL over 20 minutes. The precipitated powder was collected by filtration and dried to obtain 19 g of a resin (1).

### Solvent Fractionation

The obtained resin was dissolved in 180 g of tetrahydrofuran, and the solution was poured into 200 g of a mixed solvent of hexane/ethyl acetate=90/10 (volume ratio: the same applies to the following). A solution of the upper layer was removed by decantation, and a separated oily compound was collected and dissolved again in 120 mL of THF. Subsequently, the resulting solution was added dropwise to a mixed solvent of hexane/ethyl acetate=90/10, the amount of which was 10 times the amount of the solution, to obtain a resin (1-2). The above operation was performed three times to obtain 17 g of a target resin (B-1). The obtained resin had a weight-average molecular weight of 21,700 and a dispersity (Mw/Mn) of 1.7.

### Synthesis Example 2: Synthesis of Resin B-2

### Radical Polymerization

Under a stream of nitrogen, 8.6 g of cyclohexanone was placed in a three-necked flask, and the flask was heated to 80° C. A solution prepared by dissolving, in 79 g of cyclohexanone, 8.0 g of 2-methoxyethyl acrylate, 2.9 g of normal-butyl acrylate, 7.1 g of cyclohexyl acrylate, 2.0 g of methacrylic acid, and a polymerization initiator V-601 (manufactured by FUJIFILM Wako Pure Chemical Corporation) in an amount of 8 mol % relative to the monomers was added dropwise thereto over six hours. After completion of the dropwise addition, the reaction mixture was further reacted at 80° C. for two hours. The reaction mixture was allowed to cool and then added dropwise to a liquid mixture of hexane 800 mL/ethyl acetate 200 mL over 20 minutes. The precipitated powder was collected by filtration and dried to obtain 19 g of a resin (1).

### Solvent Fractionation

The obtained resin was dissolved in 180 g of tetrahydrofuran, and the solution was poured into 200 g of a mixed solvent of hexane/ethyl acetate=90/10. A solution of the upper layer was removed by decantation, and a separated oily compound was collected and dissolved again in 120 mL of THF. Subsequently, the resulting solution was added dropwise to a mixed solvent of hexane/ethyl acetate=90/10, the amount of which was 10 times the amount of the solution, to obtain a resin (1-2). The above operation was performed once to obtain 19 g of a target resin (B-2). The obtained resin had a weight-average molecular weight of 25,000 and a dispersity (Mw/Mn) of 2.9.

### Synthesis Example 3: Synthesis of Resin B-3

### Radical Polymerization

Under a stream of nitrogen, 8.6 g of cyclohexanone was placed in a three-necked flask, and the flask was heated to 80° C. A solution prepared by dissolving, in 79 g of cyclohexanone, 8.0 g of 2-methoxyethyl acrylate, 2.9 g of normal-butyl acrylate, 7.1 g of cyclohexyl acrylate, 2.0 g of methacrylic acid, and a polymerization initiator V-601 (manufactured by FUJIFILM Wako Pure Chemical Corporation) in an amount of 8 mol % relative to the monomers was added dropwise thereto over six hours. After completion of the dropwise addition, the reaction mixture was further reacted at 80° C. for two hours. The reaction mixture was allowed to cool and then added dropwise to a liquid mixture of hexane 800 mL/ethyl acetate 200 mL over 20 minutes. The precipitated powder was collected by filtration and dried to obtain 19 g of a resin (1).

### Solvent Fractionation

The obtained resin was dissolved in 180 g of tetrahydrofuran, and the solution was poured into 200 g of a mixed solvent of hexane/ethyl acetate=90/10. A solution of the upper layer was removed by decantation, and a separated oily compound was collected and dissolved again in 120 mL of THF. Subsequently, the resulting solution was added dropwise to a mixed solvent of hexane/ethyl acetate=90/10, the amount of which was 10 times the amount of the solution, to obtain a resin (2-2). The above operation was performed twice to obtain 18 g of a target resin (B-3). The obtained resin had a weight-average molecular weight of 25,800 and a dispersity (Mw/Mn) of 2.1.

### Synthesis Example 4: Synthesis of Resin B-17

### Radical Polymerization

Under a stream of nitrogen, 8.6 g of cyclohexanone was placed in a three-necked flask, and the flask was heated to 80° C. A solution prepared by dissolving, in 79 g of cyclohexanone, 7.1 g of 2-methoxyethyl acrylate, 2.6 g of normal-butyl acrylate, 8.5 g of tetrahydrobicyclopentadienyl acrylate, 1.8 g of methacrylic acid, and a polymerization initiator V-601 (manufactured by FUJIFILM Wako Pure Chemical Corporation) in an amount of 8 mol % relative to the monomers was added dropwise thereto over six hours. After completion of the dropwise addition, the reaction mixture was further reacted at 80° C. for two hours. The reaction mixture was allowed to cool and then added dropwise to a liquid mixture of hexane 800 mL/ethyl acetate 200 mL over 20 minutes. The precipitated powder was collected by filtration and dried to obtain 19 g of a target resin (2).

### Solvent Fractionation

The obtained resin was dissolved in 180 g of tetrahydrofuran, and the solution was poured into 200 g of a mixed solvent of hexane/ethyl acetate=90/10. A solution of the upper layer was removed by decantation, and a separated oily compound was collected and dissolved again in 120 mL of THF. Subsequently, the resulting solution was added dropwise to a mixed solvent of hexane/ethyl acetate=90/10, the amount of which was 10 times the amount of the solution, to obtain a resin (1-2). The above operation was performed three times to obtain 17 g of a target resin (B-17). The obtained resin had a weight-average molecular weight of 23,000 and a dispersity (Mw/Mn) of 1.7.

### Synthesis Example 5: Synthesis of Resin B-101

### Radical Polymerization

Under a stream of nitrogen, 8.6 g of cyclohexanone was placed in a three-necked flask, and the flask was heated to 80° C. A solution prepared by dissolving, in 79 g of cyclohexanone, 7.1 g of 2-methoxyethyl acrylate, 2.6 g of normal-butyl acrylate, 8.5 g of tetrahydrobicyclopentadienyl acrylate, 1.8 g of methacrylic acid, and a polymerization initiator V-601 (manufactured by FUJIFILM Wako Pure Chemical Corporation) in an amount of 8 mol % relative to the monomers was added dropwise thereto over six hours. After completion of the dropwise addition, the reaction mixture was further reacted at 80° C. for two hours. The reaction mixture was allowed to cool and then added dropwise to a liquid mixture of hexane 800 mL/ethyl acetate 200 mL over 20 minutes. The precipitated powder was collected by filtration and dried to obtain 19 g of a target resin (B-101). The obtained resin had a weight-average molecular weight of 24,300 and a dispersity (Mw/Mn) of 3.2.

### Photoacid Generator (C)

The structures of compounds used as the photoacid generator are shown below.

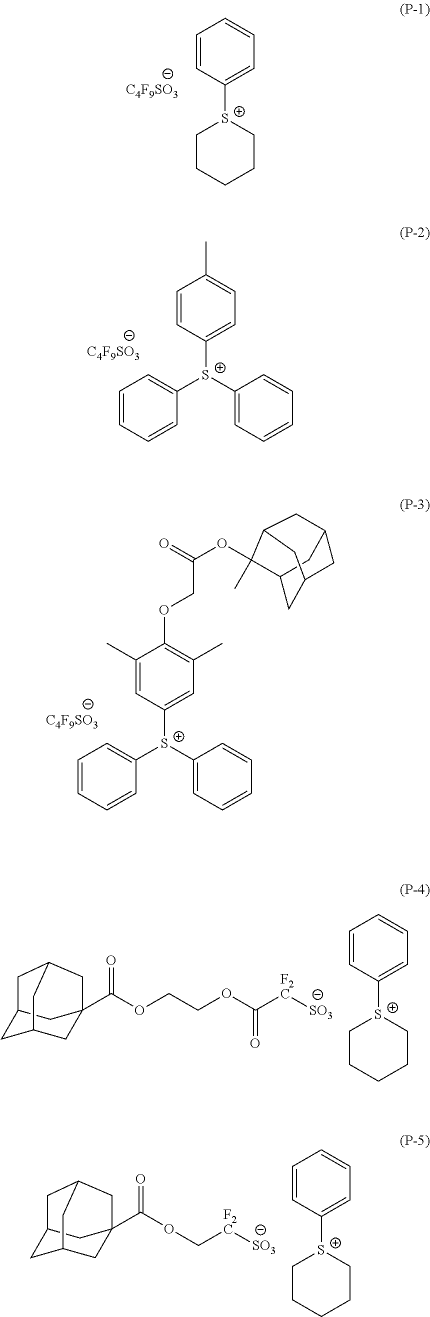

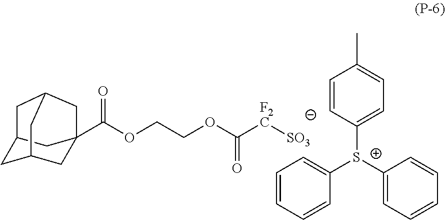

### Acid Diffusion Control Agent (D)

The structures of compounds used as the acid diffusion control agent are shown below.

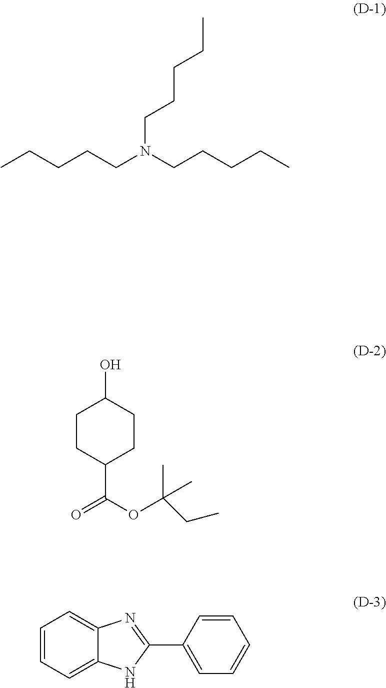 [SMILES: CCCCCN(CCCCC)CCCCC ; CCC(C)(C)OC(=O)C1CCC(O)CC1 ; c1ccc(-c2nc3ccccc3[nH]2)cc1]

### Solvent (S)

The solvents used are as follows.
S-1: propylene glycol monomethyl ether acetate
S-2: propylene glycol monomethyl ether

### Preparation of Resist Composition

Resist compositions R-1 to R-43 and RX-1 to RX-3 were each obtained by dissolving the components shown in Table 2 below in the solvents shown in the table to prepare a solution having the concentration of solid contents shown in the table, and filtering the solution through a polyethylene filter having a pore size of 3 μm.

Note that the solid contents mean all components other than the solvents. The obtained resist compositions were used in Examples and Comparative Examples.

In Table 2, units of the amounts of components (other than the solvents) added are parts by mass. The concentration of solid contents means the mass percentage of the mass of components other than the solvents relative to the total mass of each resist composition.

As the solvents, the compounds shown in Table 2 were used at the mass ratios shown in Table 2.

The content (mass %) of a compound having an ethylenically unsaturated bond and included in the total solid content of the composition according to the present invention is also described in the column of “Residual mono”. The measurement method is as described above.

TABLE 3

| | | | | Photoacid | | Acid diffusion | | | |
|---|---|---|---|---|---|---|---|---|---|
| | | Resin (A) | | generator (C) | | control agent | | Resin (B) | |
| | Resist | | Amount | | Amount | | Amount | | Amount |
| Table 2 | composition | Type | added | Type | added | Type | added | Type | added |
| Example 1 | R-1 | A-1 | 100 | P-1 | 1.0 | D-1 | 0.01 | B-1 | 10 |
| Example 2 | R-2 | A-1 | 100 | P-1 | 1.0 | D-1 | 0.01 | B-2 | 10 |
| Example 3 | R-3 | A-1 | 100 | P-1 | 1.0 | D-1 | 0.01 | B-3 | 10 |
| Example 4 | R-4 | A-1 | 100 | P-1 | 1.0 | D-1 | 0.01 | B-4 | 10 |
| Example 5 | R-5 | A-1 | 100 | P-1 | 1.0 | D-1 | 0.01 | B-5 | 10 |
| Example 6 | R-6 | A-1 | 100 | P-1 | 1.0 | D-1 | 0.01 | B-1 | 60 |
| Example 7 | R-7 | A-1 | 100 | P-1 | 1.0 | D-1 | 0.01 | B-1 | 40 |
| Example 8 | R-8 | A-1 | 100 | P-1 | 1.0 | D-1 | 0.01 | B-6 | 10 |
| Example 9 | R-9 | A-1 | 100 | P-1 | 1.0 | D-1 | 0.01 | B-7 | 10 |
| Example 10 | R-10 | A-1 | 100 | P-1 | 1.0 | D-1 | 0.01 | B-8 | 10 |
| Example 11 | R-11 | A-1 | 100 | P-1 | 1.0 | D-1 | 0.01 | B-9 | 10 |
| Example 12 | R-12 | A-1 | 100 | P-1 | 1.0 | D-1 | 0.01 | B-10 | 10 |
| Example 13 | R-13 | A-1 | 100 | P-1 | 1.0 | D-1 | 0.01 | B-11 | 10 |
| Example 14 | R-14 | A-1 | 100 | P-1 | 1.0 | D-1 | 0.01 | B-12 | 10 |
| Example 15 | R-15 | A-1 | 100 | P-1 | 1.0 | D-1 | 0.01 | B-13 | 10 |
| Example 16 | R-16 | A-1 | 100 | P-1 | 1.0 | D-1 | 0.01 | B-14 | 10 |
| Example 17 | R-17 | A-1 | 100 | P-1 | 1.0 | D-1 | 0.01 | B-15 | 10 |
| Comparative | RX-1 | A-1 | 100 | P-1 | 1.0 | D-1 | 0.01 | B-101 | 10 |
| Example 1 | | | | | | | | | |
| Comparative | RX-2 | A-1 | 100 | P-1 | 1.0 | D-1 | 0.01 | B-102 | 10 |
| Example 2 | | | | | | | | | |
| Comparative | RX-3 | A-1 | 100 | P-1 | 1.0 | D-1 | 0.01 | B-103 | 10 |
| Example 3 | | | | | | | | | |

| | | | | | Concentration | | Defects |
|---|---|---|---|---|---|---|---|
| | Solvent | | | | of solid | | after |
| | | Content | | Content | contents | Residual | lapse of |
| Table 2 | Type | ratio | Type | ratio | (mass %) | mono | time |
| Example 1 | S-1 | 133 | S-2 | 33 | 40 | 0.05 | A |
| Example 2 | S-1 | 133 | S-2 | 33 | 40 | 0.05 | B |
| Example 3 | S-1 | 133 | S-2 | 33 | 40 | 0.05 | B |
| Example 4 | S-1 | 133 | S-2 | 33 | 40 | 0.05 | C |
| Example 5 | S-1 | 133 | S-2 | 33 | 40 | 0.05 | C |
| Example 6 | S-1 | 193 | S-2 | 48 | 40 | 0.05 | C |
| Example 7 | S-1 | 169 | S-2 | 42 | 40 | 0.05 | B |
| Example 8 | S-1 | 133 | S-2 | 33 | 40 | 0.05 | B |
| Example 9 | S-1 | 133 | S-2 | 33 | 40 | 1.5 | C |
| Example 10 | S-1 | 133 | S-2 | 33 | 40 | 0.9 | B |
| Example 11 | S-1 | 133 | S-2 | 33 | 40 | 0.5 | B |
| Example 12 | S-1 | 133 | S-2 | 33 | 40 | 0.1 | B |
| Example 13 | S-1 | 133 | S-2 | 33 | 40 | 0.05 | C |
| Example 14 | S-1 | 133 | S-2 | 33 | 40 | 0.05 | C |
| Example 15 | S-1 | 133 | S-2 | 33 | 40 | 0.05 | B |
| Example 16 | S-1 | 133 | S-2 | 33 | 40 | 0.05 | B |
| Example 17 | S-1 | 133 | S-2 | 33 | 40 | 0.05 | B |
| Comparative | S-1 | 133 | S-2 | 33 | 40 | 0.05 | D |
| Example 1 | | | | | | | |
| Comparative | S-1 | 133 | S-2 | 33 | 40 | 0.05 | D |
| Example 2 | | | | | | | |
| Comparative | S-1 | 133 | S-2 | 33 | 40 | 0.05 | D |
| Example 3 | | | | | | | |

| | | | | Photoacid | | Acid diffusion control | | | |
|---|---|---|---|---|---|---|---|---|---|
| | | Resin (A) | | generator (C) | | agent | | Resin (B) | |
| Table 2 | Resist | | Amount | | Amount | | Amount | | Amount |
| (Continued) | composition | Type | added | Type | added | Type | added | Type | added |
| Example 18 | R-18 | A-2 | 100 | P-1 | 1.0 | D-1 | 0.01 | B-1 | 10 |
| Example 19 | R-19 | A-1 | 100 | P-2 | 1.0 | D-1 | 0.01 | B-1 | 10 |
| Example 20 | R-20 | A-1 | 100 | P-3 | 1.0 | D-1 | 0.01 | B-1 | 10 |
| Example 21 | R-21 | A-1 | 100 | P-4 | 1.0 | D-1 | 0.01 | B-1 | 10 |
| Example 22 | R-22 | A-1 | 95 | P-5 | 1.0 | D-1 | 0.01 | B-1 | 10 |
| Example 23 | R-23 | A-1 | 110 | P-6 | 1.0 | D-1 | 0.01 | B-1 | 10 |
| Example 24 | R-24 | A-1 | 100 | P-1 | 1.0 | D-1 | 0.01 | B-16 | 10 |
| Example 25 | R-25 | A-1 | 100 | P-1 | 1.2 | D-1 | 0.01 | B-17 | 10 |
| Example 26 | R-26 | A-1 | 100 | P-1 | 0.9 | D-1 | 0.01 | B-18 | 10 |
| Example 27 | R-27 | A-1 | 120 | P-1 | 1.0 | D-1 | 0.0 | B-19 | 10 |
| Example 28 | R-28 | A-1 | 100 | P-1 | 1.0 | D-1 | 0.01 | B-20 | 10 |
| Example 29 | R-29 | A-1 | 100 | P-1 | 1.0 | D-1 | 0.01 | B-21 | 10 |
| Example 30 | R-30 | A-1 | 100 | P-1 | 1.0 | D-1 | 0.02 | B-22 | 10 |
| Example 31 | R-31 | A-1 | 100 | P-1 | 1.0 | D-1 | 0.01 | B-23 | 10 |
| Example 32 | R-32 | A-1 | 100 | P-1 | 1.0 | D-1 | 0.008 | B-24 | 10 |
| Example 33 | R-33 | A-1 | 100 | P-1 | 1.0 | D-1 | 0.01 | B-25 | 10 |
| Example 34 | R-34 | A-1 | 100 | P-1 | 1.0 | D-1 | 0.01 | B-26 | 10 |
| Example 35 | R-35 | A-1 | 100 | P-1 | 1.0 | D-1 | 0.01 | B-27 | 10 |
| Example 36 | R-36 | A-1 | 100 | P-1 | 1.0 | D-1 | 0.01 | B-28 | 10 |
| Example 37 | R-37 | A-1 | 100 | P-1 | 1.0 | D-1 | 0.01 | B-29 | 10 |
| Example 38 | R-38 | A-1 | 100 | P-1 | 1.0 | D-2 | 0.01 | B-1 | 10 |
| Example 39 | R-39 | A-1 | 100 | P-1 | 1.0 | D-3 | 0.01 | B-1 | 10 |
| Example 40 | R-40 | A-1/A-2 | 50/50 | P-1 | 1.0 | D-1 | 0.01 | B-1 | 10 |
| Example 41 | R-41 | A-1 | 100 | P-4/P-5 | 0.5/0.5 | D-1 | 0.01 | B-1 | 10 |
| Example 42 | R-42 | A-1 | 100 | P-1 | 1.0 | D-1 | 0.01 | B-1/B-20 | 5/5 |
| Example 43 | R-43 | A-1 | 100 | P-1 | 1.0 | D-1/D-2 | 0.005/0.005 | B-1 | 10 |

| | | | | | Concentration | | Defects |
|---|---|---|---|---|---|---|---|
| | Solvent | | | | of solid | | after |
| Table 2 | | Content | | Content | contents | Residual | lapse |
| (Continued) | Type | ratio | Type | ratio | (mass %) | mono | of time |
| Example 18 | S-1 | 133 | S-2 | 33 | 40 | 0.05 | B |
| Example 19 | S-1 | 133 | S-2 | 33 | 40 | 0.05 | A |
| Example 20 | S-1 | 133 | S-2 | 33 | 40 | 0.05 | A |
| Example 21 | S-1 | 133 | S-2 | 33 | 40 | 0.05 | A |
| Example 22 | S-1 | 127 | S-2 | 32 | 40 | 0.05 | A |
| Example 23 | S-1 | 145 | S-2 | 36 | 40 | 0.05 | A |
| Example 24 | S-1 | 133 | S-2 | 33 | 40 | 0.05 | B |
| Example 25 | S-1 | 133 | S-2 | 33 | 25 | 0.05 | B |
| Example 26 | S-1 | 133 | S-2 | 33 | 30 | 0.05 | A |
| Example 27 | S-1 | 157 | S-2 | 39 | 40 | 0.05 | A |
| Example 28 | S-1 | 133 | S-2 | 33 | 40 | 0.05 | A |
| Example 29 | S-1 | 133 | S-2 | 33 | 40 | 0.05 | A |
| Example 30 | S-1 | 133 | S-2 | 33 | 40 | 0.05 | A |
| Example 31 | S-1 | 133 | S-2 | 33 | 40 | 0.05 | A |
| Example 32 | S-1 | 133 | S-2 | 33 | 40 | 0.05 | A |
| Example 33 | S-1 | 133 | S-2 | 33 | 40 | 0.05 | A |
| Example 34 | S-1 | 133 | S-2 | 33 | 40 | 0.05 | A |
| Example 35 | S-1 | 144 | S-2 | 22 | 40 | 0.05 | A |
| Example 36 | S-1 | 128 | S-2 | 38 | 40 | 0.05 | A |
| Example 37 | S-1 | 133 | S-2 | 33 | 40 | 0.05 | A |
| Example 38 | S-1 | 133 | S-2 | 33 | 40 | 0.05 | A |
| Example 39 | S-1 | 133 | S-2 | 33 | 40 | 0.05 | A |
| Example 40 | S-1 | 133 | S-2 | 33 | 40 | 0.05 | A |
| Example 41 | S-1 | 133 | S-2 | 33 | 40 | 0.05 | A |
| Example 42 | S-1 | 133 | S-2 | 33 | 40 | 0.05 | A |
| Example 43 | S-1 | 133 | S-2 | 33 | 40 | 0.05 | A |

A spin coater ACT-8 manufactured by Tokyo Electron Ltd. was used to apply the resist composition shown in Table 2 above onto a Si substrate subjected to hexamethyldisilazane treatment (manufactured by Advanced Materials Technology, Inc.) without providing an antireflection layer, and drying was performed by heating at 120° C. for 60 seconds to form an actinic ray-sensitive or radiation-sensitive film (resist film) having a thickness of 10 μm.

The wafer on which the resist film was formed was subjected to pattern exposure through an exposure mask using a KrF excimer laser scanner (manufactured by ASML, PAS5500/850C, wavelength: 248 nm, NA: 0.50). Subsequently, the wafer was baked (Post Exposure Bake; PEB) at a temperature of 110° C. for 60 seconds, then immersed in a 2.38 mass % aqueous solution of tetramethylammonium hydroxide (TMAH) for 60 seconds, then rinsed with water for 30 seconds, and dried.

The exposure was performed through a mask having a line-and-space pattern that could provide a space pattern of 2 μm and a pitch of 22 μm after reduction projection exposure. An exposure dose that could form a space pattern of 2 μm and a pitch of 22 μm was defined as an optimum exposure dose (sensitivity) (mJ/cm²). The space pattern width was measured using a scanning electron microscope (SEM) (9380I manufactured by Hitachi, Ltd.). Through the above procedure, a pattern wafer for evaluation, the pattern wafer having a substrate and a pattern (resist pattern) formed on a surface of the substrate, was obtained.

Defects after the lapse of time were evaluated as described below.

Evaluation of Defects after Lapse of Time (Defects after Lapse of Time)

The resist composition (which had been stored at room temperature (25° C.)) for three days or less after the preparation was used to form the above isolated pattern having a thickness of 10 μm (isolated space pattern of 2 μm). For the obtained pattern, the total number of defects in the wafer (total number of defects) was measured using a surface-defect inspection device (manufactured by KLA-Tencor Corporation, product name: KLA2360). The number of wafers provided for this measurement was two for each example, and the average value was used as the “initial number of defects”.

Thereafter, the resist composition was stored at room temperature for six months, a resist pattern was then formed in the same manner, and the same evaluation as described above was performed to measure the “number of defects after lapse of time”.

The temporal stability of the number of defects was evaluated on the basis of the following criteria.

(Temporal stability of number of defects)=(number of defects after lapse of time)−(initial number of defects)
A: less than 10
B: 10 or more and less than 100
C: 100 or more and less than 1,000
D: 1,000 or more

The obtained results are shown in Table 2.

As can be seen from Table 2, the resist compositions of Examples could reduce the defects in the pattern after the lapse of time.

What is claimed is:

1. An actinic ray-sensitive or radiation-sensitive resin composition having a concentration of solid contents of 15% or more, the resin composition comprising:
(A) a resin including a repeating unit (a1) having an acid-decomposable group and a repeating unit (a2) having an aromatic ring;
(B) a resin including a repeating unit (b1) represented by General formula (1) below; and
(C) a compound that generates an acid upon irradiation with an actinic ray or a radiation,
wherein a content of a repeating unit having an acid-decomposable group and included in the resin (B) is 5 mol % or less relative to all repeating units in the resin (B), and the resin (B) has a dispersity of less than 3.0, 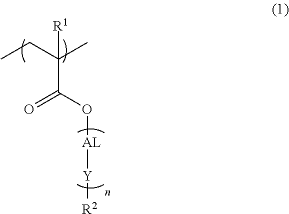
in General formula (1),
R¹ and R² each independently represent a hydrogen atom or a hydrocarbon group,
AL represents a linear or branched alkylene group, and when n represents an integer of 2 or more, a plurality of AL's may be the same or different from each other, provided that each AL does not include an acid-decomposable group,
Y represents —O—, —S—, —COO—, or —OCO—, and when n represents an integer of 2 or more, a plurality of Y's may be the same or different from each other, and
n represents an integer of 1 or more.

2. The actinic ray-sensitive or radiation-sensitive resin composition according to claim 1, wherein, in the General formula (1), AL is an ethylene group, and Y is —O—.

3. The actinic ray-sensitive or radiation-sensitive resin composition according to claim 1, wherein the resin (B) includes a repeating unit (b2) having a carboxyl group or a hydroxyl group.

4. The actinic ray-sensitive or radiation-sensitive resin composition according to claim 1, wherein a content of the resin (B) is 50 parts by mass or less relative to 100 parts by mass of the resin (A).

5. The actinic ray-sensitive or radiation-sensitive resin composition according to claim 1, wherein the resin (B) does not substantially include a fluorine atom or a silicon atom.

6. The actinic ray-sensitive or radiation-sensitive resin composition according to claim 1, wherein a content of a compound having an ethylenically unsaturated bond and included in the composition is 1.0 mass % or less in a total solid content.

7. The actinic ray-sensitive or radiation-sensitive resin composition according to claim 1, wherein, in a chromatogram obtained by gel permeation chromatography (GPC) of the resin (B), an area of a component having a weight-average molecular weight (Mw_{B}) of 10,000 or less is 20% or less with respect to a total area excluding peak areas of an unreacted polymerizable monomer and a polymerization solvent, and the resin (B) has a Mw_{B} of 90,000 or less.

8. An actinic ray-sensitive or radiation-sensitive film formed from the actinic ray-sensitive or radiation-sensitive resin composition according to claim 1.

9. A pattern forming method comprising:
forming an actinic ray-sensitive or radiation-sensitive film on a substrate from the actinic ray-sensitive or radiation-sensitive resin composition according to claim 1;
exposing the actinic ray-sensitive or radiation-sensitive film; and
developing the exposed actinic ray-sensitive or radiation-sensitive film with a developer to form a pattern.

10. A method for producing an electronic device, the method comprising the pattern forming method according to claim 9.
